(19) United States
(12) Patent Application Publication
(10) Pub. No.: US 2013/0300984 A1
(43) Pub. Date: Nov. 14, 2013

(54) LIGHT SOURCE PACKAGE STRUCTURE, FABRICATING METHOD THEREOF AND LIQUID CRYSTAL DISPLAY

(71) Applicant: ASDA TECHNOLOGY CO., LTD., Hsinchu (TW)

(72) Inventor: Pao-Ting LIN, HSINCHU (TW)

(21) Appl. No.: 13/944,700

(22) Filed: Jul. 17, 2013

Related U.S. Application Data
(63) Continuation of application No. PCT/CN2011/084379, filed on Dec. 22, 2011.

(30) Foreign Application Priority Data
Jan. 17, 2011 (CN) 201110023496.0

(51) Int. Cl. H01L 33/50; G02F 1/1335

(52) U.S. Cl. CPC H01L 33/501; G02F 1/133603
USPC 349/69; 438/27; 257/88

(57) ABSTRACT

The present invention discloses a light source package structure, a fabricating method thereof and a liquid crystal display. The light source package structure includes two overlapped substrates, a frame-shaped resin body, a filling material layer and a photoluminescence object. The frame-shaped resin body is positioned between the two substrates and encloses a vacuum space together with the two substrates. The photoluminescence object is positioned in the vacuum space. The filling material layer with light transmittance is fully filled in the vacuum space and wraps the photoluminescence object. In various embodiments of the present invention, the photoluminescence object is a phosphor powder layer, a light emitting diode module or a combination thereof.

### RELATED APPLICATIONS

This application is a continuation of International application No. PCT/CN2011/084379, filed on Dec. 22, 2011, which claims priority to China Application Serial Number 201110023496.0, filed Jan. 17, 2011, which is herein incorporated by reference.

### BACKGROUND

1. Field of Invention

The present invention relates to a package structure. More particularly, the present invention relates to a light source package structure, a fabricating method thereof and a liquid crystal display.

2. Description of Related Art

In a package application of conventional light emitting diodes (LEDs), an epoxy resin for example is used as resin material of an outer package layer of the LED. The epoxy resin trends to crack and change its color, resulting in a decrease of the product life thereof. In addition, the light source emitted from the LED (especially a blue-white light) includes an ultraviolet light (UV) waveband. The aforesaid conditions will cause carbonization of the epoxy resin, which leads to a browned phenomenon and reduces the light extraction efficiency of the LED.

In view of the above, the epoxy resin is replaced by a silicone resin material as the outer package layer of the LED in the industry. However, the silicone has high water absorbability and low air tightness, which allows the moisture to easily permeate the LED and then results in a decrease of the product life of the phosphor, and makes the phosphor loss its original performance quickly. This forces many in the industry still need to look for more suitable solutions to improve the package application performance of LEDs.

It can be seen that the aforesaid package application techniques still have inconvenience and defects and thus need to be further improved, especially for the problems of the carbonation of the epoxy resin and the moisture permeating the silicone. In order to look for more suitable solutions, those of skills in the related art all devote themselves in finding solutions. However, for such a long time, no appropriate solution is developed or completed. Thus, many in the industry are endeavoring to find ways in which to provide more appropriate package application techniques, so as to eliminate the aforesaid inconvenience.

### SUMMARY

The present invention provides a light source package structure, so as to reduce the probability of damaging the aforesaid LED or phosphor.

In an aspect of the present invention, this light source package structure includes a first substrate, a second substrate, a first frame-shaped resin body, a first filling material layer and a photoluminescence object. The first substrate is a light-transmissive glass. The second substrate is overlapped with the first substrate. The first frame-shaped resin body is positioned between the first substrate and the second substrate and is connected to the second substrate and the first substrate to enclose a first vacuum space together with the first substrate and the second substrate. The photoluminescence object is positioned in the first vacuum space. The filling material layer with light transmittance is fully filled in the first vacuum space and wraps the photoluminescence object.

In a first embodiment thereof, the photoluminescence object includes a first phosphor powder layer which is coated on a surface of the second substrate or the first substrate, or is mixed into the first filling material layer.

In the first embodiment, the first frame-shaped resin body is a heat-curing resin or a light-curing resin. The first filling material layer is a liquid crystal molecule liquid, silicon oil or silica gel. Both of the first substrate and the second substrate are light-transmissive glasses.

In an option of the first embodiment, the first phosphor powder layer consists of phosphor powder blocks with various light emitting wavebands, wherein these phosphor powder blocks with different light emitting wavebands are arranged at intervals.

In an option of the first embodiment, the light source package structure further includes a light source module. The light source module is positioned at one side of the second substrate back to the first vacuum space, and emits light towards the first phosphor powder layer and the first substrate.

In a variation of this option, the light source module is a top view type LED module.

In another variation of this option, the light source module is a side view type LED.

In a further variation of this option, the light source module includes a third substrate, a second frame-shaped resin body, a first light-transmissive circuit layer, a second filling material layer and a first LED module. The second frame-shaped resin body is positioned between the second substrate and the third substrate and encloses a second vacuum space together with the second substrate and the third substrate. The first light-transmissive circuit layer is flat placed on the third substrate and positioned in the second vacuum space. The second filling material layer is fully filled in the second vacuum space. The first LED module is arranged on the first light-transmissive circuit layer and electrically connected to the first light-transmissive circuit layer.

In a variation of this option, the second frame-shaped resin body is a heat-curing resin or a light-curing resin. The second filling material layer is a liquid crystal molecule liquid, silicon oil or silica gel.

The light source module may further include a first reflective layer and a first insulating layer. The first reflective layer is positioned on one side surface of the third substrate facing the first substrate. The first insulating layer is stacked between the first reflective layer and the first light-transmissive circuit layer.

In an option of the first embodiment, for a variation of this option, the first LED module may include a red LED chip, a green LED chip and a blue LED chip.

In a second embodiment of the aspect, the photoluminescence object includes a second LED module. The light source package structure further includes a second light-transmissive circuit layer. The second light-transmissive circuit layer is flat placed on the second substrate or the first substrate. The second LED module is arranged on the second light-transmissive circuit layer and electrically connected to the second light-transmissive circuit layer. The second substrate is a light-transmissive glass, a metal plate, a ceramic plate or a silicon substrate.

Furthermore, in an option of the second embodiment, the area of the second substrate is larger than that of the first substrate, and the second light-transmissive circuit layer extends out of the first vacuum space.

Furthermore, in an option of the second embodiment, the light source package structure further includes a second reflective layer and a second insulating layer. The second reflective layer is positioned on one side surface of the second substrate facing the first substrate. The second insulating layer is stacked between the second reflective layer and the second light-transmissive circuit layer. The second reflective layer includes a base material and a reflective film. The base material is directly stacked on one surface of the second substrate. The reflective film is directly stacked between the base material and the second insulating layer.

In an option of the second embodiment, the second LED module includes LED chips with different colors of emitted lights.

In a third embodiment of the aspect, the photoluminescence object further includes a second LED module and a second phosphor powder layer.

In an option of the third embodiment, the second phosphor powder layer is coated on the second LED module so that the second LED module is positioned between the second phosphor powder layer and the second light-transmissive circuit layer.

In an option of the third embodiment, the second phosphor powder layer is coated on the surface of the first substrate so that the second LED module is positioned between the second phosphor powder layer and the second light-transmissive circuit layer.

The present invention further provides a liquid crystal display (LCD). The LCD includes a liquid crystal panel and the aforesaid light source package structure. The liquid crystal panel includes an upper substrate and a liquid crystal layer, wherein the liquid crystal layer is directly sandwiched between the first substrate and the upper substrate.

The liquid crystal panel further includes a colored filter. The colored filter is positioned at one side of the upper substrate far away from the liquid crystal layer. The colored filter includes a red pixel grating, a green pixel grating and a blue pixel grating. The first phosphor powder layer includes a red phosphor powder block, a green phosphor powder block and a blue phosphor powder block, which are arranged at intervals. The red phosphor powder block directly faces the red pixel grating; the green phosphor powder block directly faces the green pixel grating; and the blue phosphor powder block directly faces the blue pixel grating.

The present invention also provides a fabricating method of the aforesaid light source package structure, and the method approximately includes the following steps. A first substrate and a second substrate are provided. A resin layer is formed on the surface of the second substrate, wherein the resin layer has an enclosed area with an opening. The first substrate is covered on the second substrate, so as to enclose an internal space between the resin layer, the first substrate and the second substrate. The resin layer is cured. A filling material is filled into the internal space through the opening. Then the opening is sealed up to seal the filling material in the internal space.

In an embodiment of this fabricating method, after the resin layer is formed on the surface of the second substrate, the method further includes the following steps. A phosphor powder layer is directly formed on the surface of the first substrate or the second substrate, so that the phosphor powder layer is positioned in the internal space after the first substrate covers on the second substrate.

In another embodiment of this fabricating method, the step of providing the second substrate further includes the following steps. A light-transmissive circuit layer is formed on the second substrate. A LED module is arranged on the light-transmissive circuit layer, wherein the LED module is electrically connected to the light-transmissive circuit layer.

In a further embodiment of this fabricating method, after the resin layer is formed on the surface of the second substrate, the method further includes the following steps. A phosphor powder layer is formed on the LED module, so that the LED module is positioned between the phosphor powder layer and the light-transmissive circuit layer after the first substrate covers on the second substrate.

In yet a further embodiment of this fabricating method, the step of filling a filling material into the internal space through the opening further includes the following steps. The internal space is maintained under a vacuum negative pressure state, and the filling material is introduced into the internal space through the vacuum negative pressure. The filling material is a liquid crystal molecule liquid, silicon oil or silica gel.

In view of the above, with the design of the light source package structure of the present invention, the photoluminescence object, such as the LED or the phosphor powder layer, can be packaged hermetically between the aforesaid two substrates to reduce the probability of damaging the aforesaid photoluminescence object due to changes of the external environment.

### BRIEF DESCRIPTION OF THE DRAWINGS

In order to make the aforesaid as well as other aspects, features, advantages, and embodiments of the present invention more apparent, the accompanying drawings are described as follows:

FIG. 1 illustrates a schematic side view of a light source package structure of the present invention;

FIG. 2 illustrates a schematic side view of a light source package structure in a first embodiment of the present invention;

FIG. 3 illustrates a schematic side view of the light source package structure combined with a light source module in the first embodiment of the present invention;

FIG. 4A illustrates a schematic side view of an option of the light source package structure combined with the light source module in the first embodiment of the present invention;

FIG. 4B illustrates a schematic side view of another option of the light source package structure combined with the light source module in the first embodiment of the present invention;

FIG. 4C illustrates a schematic side view of a further option of the light source package structure combined with the light source module in the first embodiment of the present invention;

FIG. 5A illustrates a schematic side view of a variation of FIG. 4C,

FIG. 5B illustrates a schematic side view of another variation of FIG. 4C,

FIG. 5C illustrates a schematic side view of a further variation of FIG. 4C,

FIG. 6 illustrates a schematic side view of an option of the light source package structure in the first embodiment of the present invention;

FIG. 7A illustrates a schematic top view of another option of the light source package structure in the first embodiment of the present invention;

FIG. 7B illustrates a schematic top view of a further option of the light source package structure in the first embodiment of the present invention;

FIG. 8 illustrates a schematic side view of the light source package structure in a second embodiment of the present invention;

FIG. 9A illustrates a schematic side view of a variation of FIG. 8;

FIG. 9B illustrates a schematic side view of another variation of FIG. 8;

FIG. 9C illustrates a schematic side view of a further variation of FIG. 8;

FIG. 9D illustrates a schematic side view of yet a further variation of FIG. 8;

FIG. 10 illustrates a schematic side view of the light source package structure in a third embodiment of the present invention;

FIG. 11A illustrates a schematic side view of a light source package structure, which is a variation of the third embodiment of the present invention;

FIG. 11B illustrates a schematic side view of a light source package structure, which is another variation of the third embodiment of the present invention;

FIG. 11C illustrates a schematic side view of a light source package structure, which is a further variation of the third embodiment of the present invention;

FIG. 12 illustrates a schematic side view of a liquid crystal display combined with the light source package structure in a fourth embodiment of the present invention;

FIG. 13A illustrates a schematic side view of a liquid crystal display (LCD) combined with the light source package structure, which is a variation of the fourth embodiment of the present invention;

FIG. 13B illustrates a schematic side view of a LCD combined with the light source package structure, which is another variation of the fourth embodiment of the present invention;

FIG. 13C illustrates a schematic side view of a LCD combined with the light source package structure, which is a further variation of the fourth embodiment of the present invention;

FIG. 13D illustrates a schematic side view of a LCD combined with the light source package structure, which is yet a further variation of the fourth embodiment of the present invention;

FIG. 14 illustrates a schematic side view of a LCD combined with the light source package structure, which is still yet a further variation of the fourth embodiment of the present invention;

FIG. 15A illustrates a preliminary flow chart of the fabricating method of the light source package structure of the present invention;

FIG. 15B illustrates a schematic operation flow chart of the fabricating method of the light source package structure of the present invention;

FIG. 16A illustrates a partially detailed flow chart of the fabricating method of the light source package structure in the first embodiment of the present invention;

FIG. 16B illustrates a schematic operation flow chart of the fabricating method of the light source package structure in the first embodiment of the present invention;

FIG. 17A illustrates a partially detailed flow chart of the fabricating method of the light source package structure in the second embodiment of the present invention;

FIG. 17B illustrates a schematic operation flow chart of the fabricating method of the light source package structure in the second embodiment of the present invention;

FIG. 18A illustrates a partially detailed flow chart of the fabricating method of the light source package structure in the third embodiment of the present invention; and

FIG. 18B illustrates a schematic operation flow chart of the fabricating method of the light source package structure in the third embodiment of the present invention.

### DETAILED DESCRIPTION

The spirit of the present invention will be described clearly through the drawings and the detailed description as follows. Any of those of ordinary skills in the art can make modifications and variations from the technology taught in the present invention after understanding the embodiments of the present invention, without departing from the sprite and scope of the present invention.

The present invention provides a light source package structure and a fabricating method thereof, to reduce the probability of damaging the photoluminescence object in the package structure due to changes of the external environment.

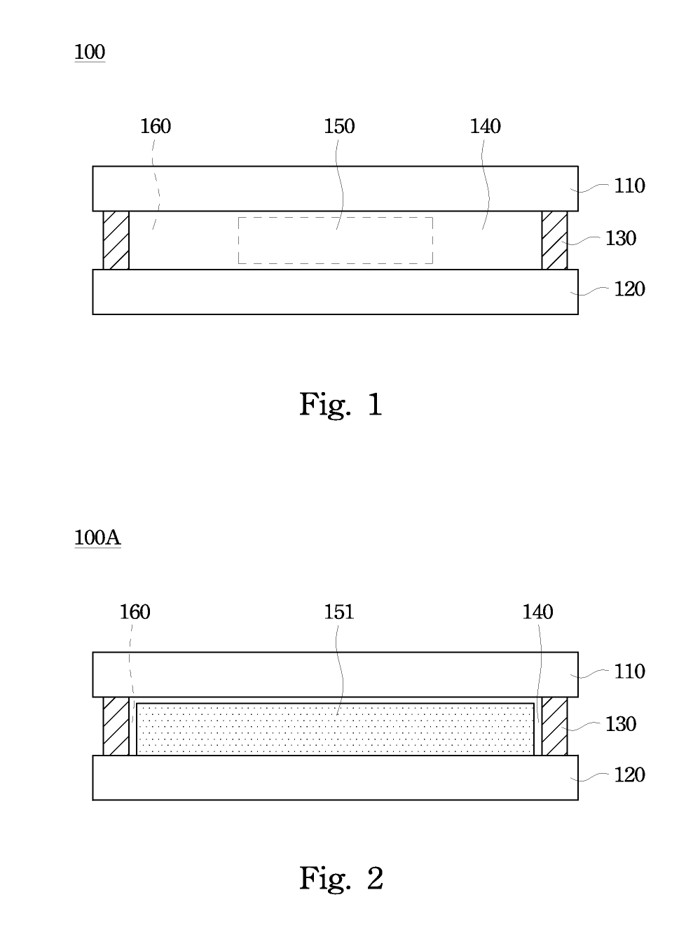

Reference is now made to FIG. 1. FIG. 1 illustrates a schematic side view of a light source package structure of the present invention. In one embodiment of the present invention, referring to FIG. 1, the light source package structure 100 includes a first substrate 110, a second substrate 120, a frame-shaped resin body 130, a first filling material layer 140 and a photoluminescence object 150. The second substrate 120 is overlapped with the first substrate 110. The first frame-shaped resin body 130 is sandwiched between the first substrate 110 and the second substrate 120, and is connected to the second substrate 120 and the first substrate 110. Furthermore, an enclosed area is included in the first frame-shaped resin body 130, so as to enclose a first vacuum space 160 insulated from the outside air among the first frame-shaped resin body 130, the first substrate 110 and the second substrate 120. The photoluminescence object 150 (details thereof are described hereafter) is contained in the first vacuum space 160. The first filling material layer 140 with light transmittance is fully filled in the first vacuum space 160, and covers and wraps the photoluminescence object 150, so that the photoluminescence object 150 can be insulated from the air. In this way, the photoluminescence object 150 does not contact the air, which maintains the original performance and extends product life thereof.

In this embodiment, the first frame-shaped resin body 130 may be a heat-curing resin or a light-curing resin (such as a UV light-curing resin), which can prevent the external air or moisture from permeating. The first filling material layer 140 may be a polymer-stabilized transparent fluid (such as silicon oil) or liquid crystal molecule liquid or transparent gel (such as silica gel). The photoluminescence object 150 may be a passive luminophor, such as the phosphor powder (body) (as described in a first embodiment hereafter); or the photoluminescence object 150 may be an active luminophor, such as the LED (as described in a second embodiment hereafter); or alternatively, the photoluminescence object 150 may include both of the passive luminophor and the active luminophor (as described in the second embodiment hereafter).

Reference is now made to FIG. 2. FIG. 2 illustrates a schematic side view of a light source package structure 100A in a first embodiment of the present invention. In the first embodiment, the photoluminescence object 150 includes a first phosphor powder layer 151. The first phosphor powder layer 151 is formed by a large number of phosphor powder particles gathered together. In the first vacuum space 160, the first phosphor powder layer 151 may be coated on the surface of the first substrate 110 or the second substrate 120, or may also be mixed into the first filling material layer 140 or even uniformly mixed into the first filling material layer 140 (not shown). The first substrate 110 and the second substrate 120 are light-transmissive substrates, such as light-transmissive glasses. Thus, compared to the package of the prior art, the light source package structure 100A of the present invention can completely separate the phosphor powder from the external environment, so that the phosphor powder will not be oxidized by the air, cracked by the external temperature or eroded by the permeated moisture, thereby greatly improving the product life and reliability of products.

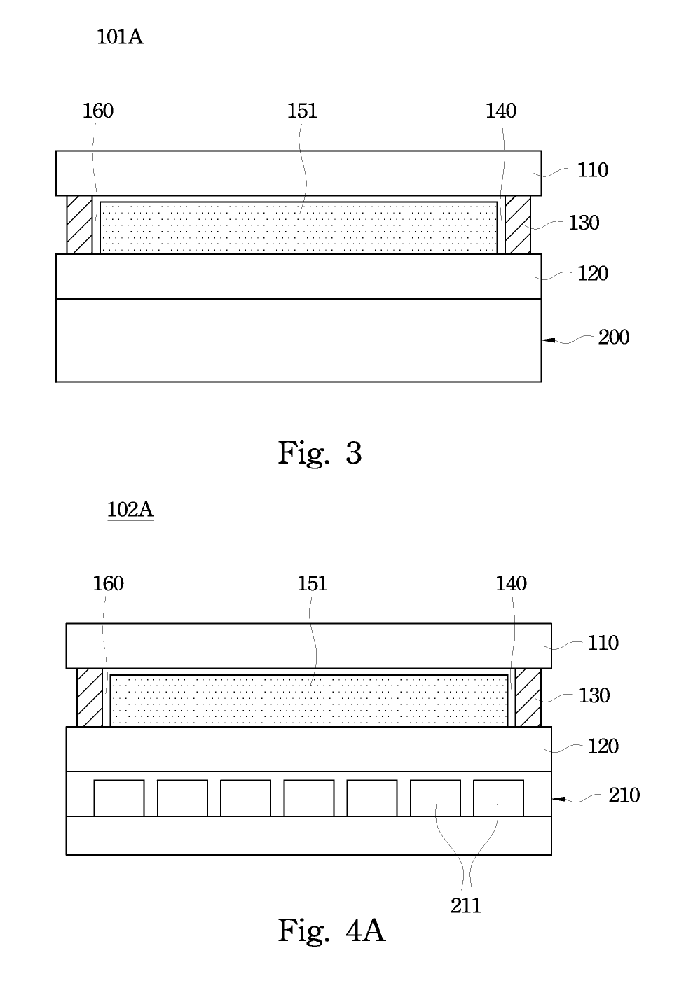

Reference is now made to FIG. 3. FIG. 3 illustrates a schematic side view of a light source package structure 101A combined with a light source module 200 in the first embodiment of the present invention. The light source package structure 101A further includes a light source module 200. The light source module 200 is positioned at one side of the second substrate 120 opposite to the first vacuum space 160, and emits light towards the first phosphor powder layer 151 and the first substrate 110. The light source module 200 may be a light emitting source with a conventional structure, such as a lighting tube and a LED. For example, when a visible light (such as blue light) is emitted by the light source module 200, the first phosphor powder layer 151 can convert the light from the light source module 200 into a white light. Alternatively, when the light source module 200 emits for example an invisible light (such as UV light), the first phosphor powder layer 151 can convert the invisible light into a visible light.

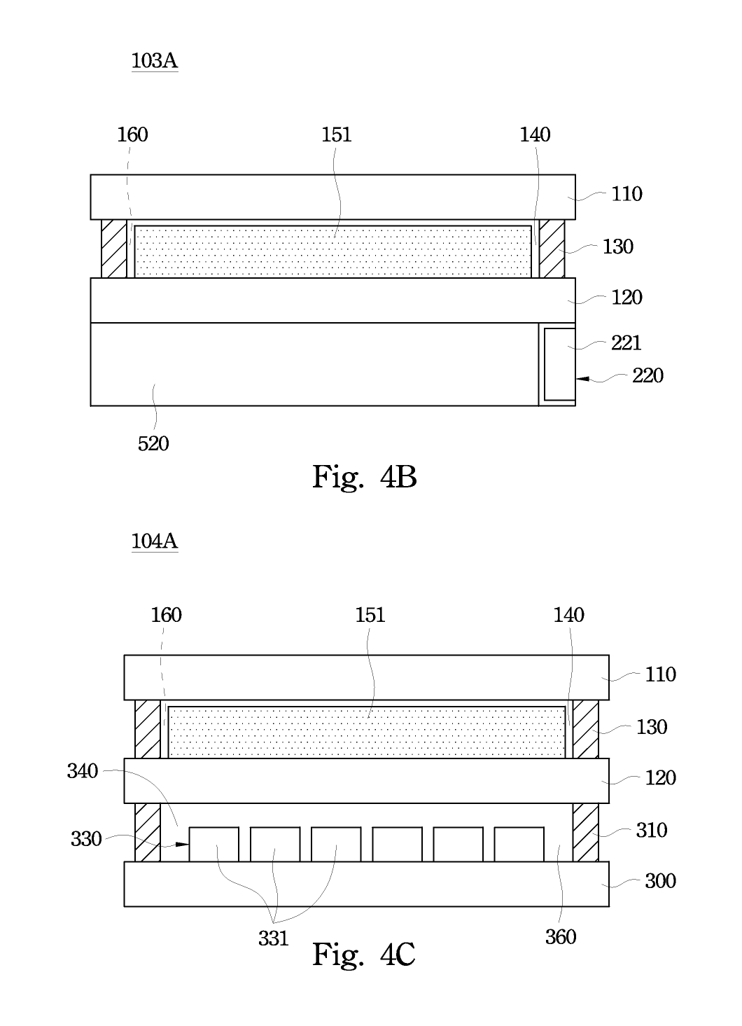

References are made to FIGS. 4A and 4B. FIG. 4A illustrates a schematic side view of an option of a light source package structure 102A combined with the light source module 200 in the first embodiment of the present invention. FIG. 4B illustrates a schematic side view of another option of a light source package structure 103A combined with the light source module 200 in the first embodiment of the present invention.

For example, the light source module 200 may be a top view type LED module 210 which has one or more LED chips 211 emitting light directly towards the first phosphor powder layer 151. The light source module 200 may be a side view type LED module 220 which has one or more LED chips 221 emitting light towards the first phosphor powder layer 151 as being directed by a light guide plate 520. Furthermore, the LED chips 211 and 221 may provide high-power light emitting performance as required.

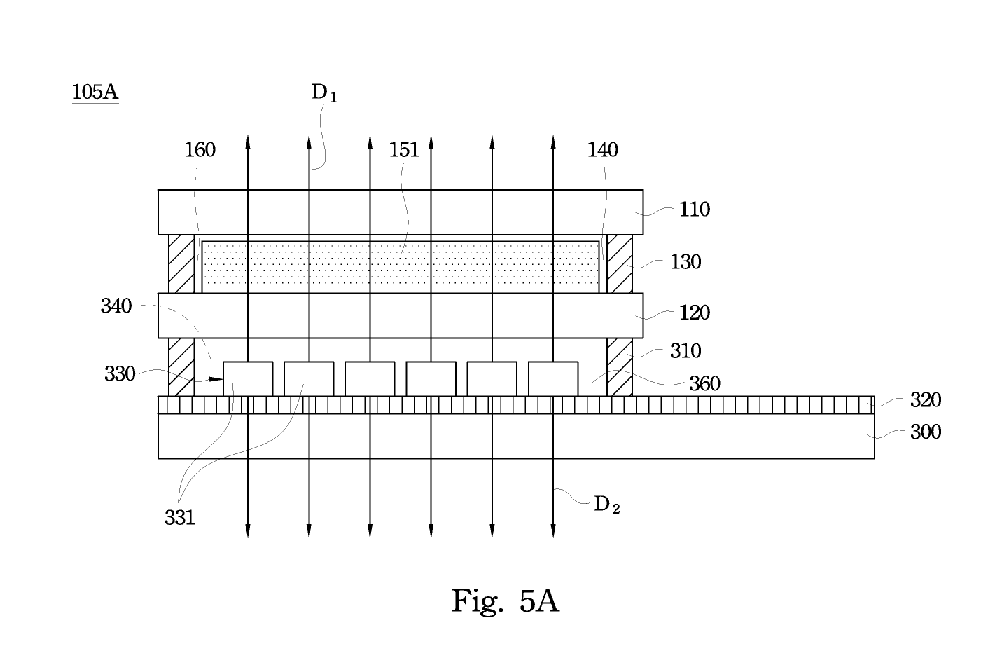

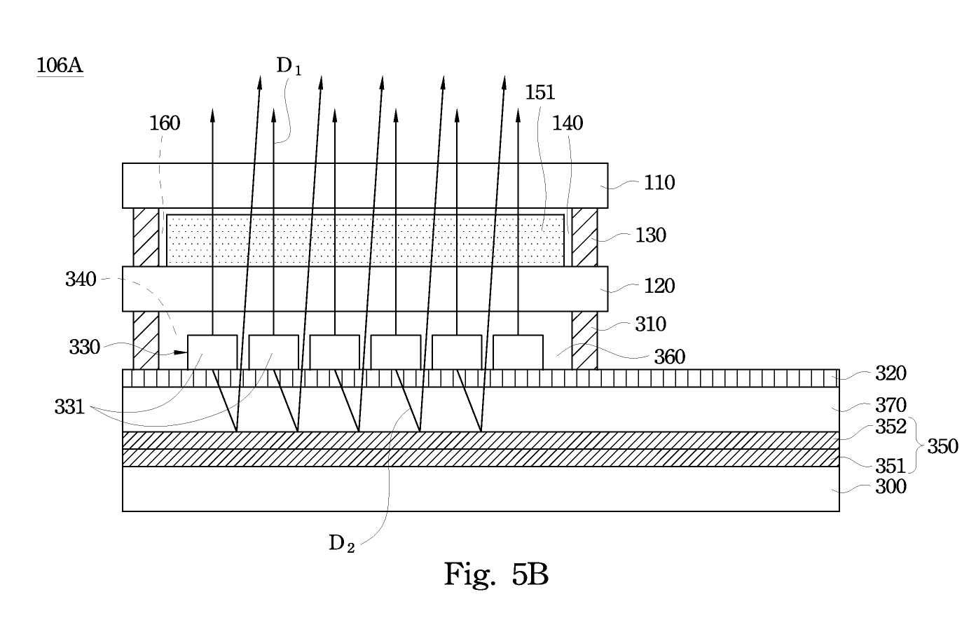

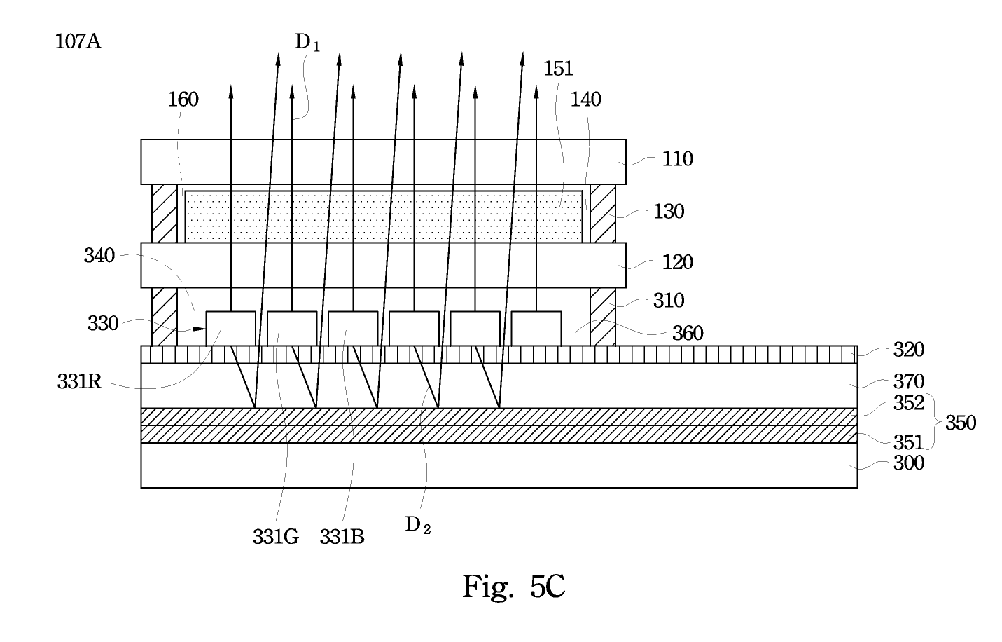

References are made to FIGS. 4C and 5A. FIG. 4C illustrates a schematic side view of a further option of a light source package structure 104A combined with the light source module 200 in the first embodiment of the present invention. FIG. 5A illustrates a schematic side view of a light source package structure 105A, which is a variation of FIG. 4C.

The light source module 200 includes a third substrate 300, a second frame-shaped resin body 310, a first light-transmissive circuit layer 320, a first LED module 330 and a second filling material layer 360. The third substrate 300 is stacked at one side of the second substrate 120 opposite to the first vacuum space 160. The second frame-shaped resin body 310 is sandwiched between the second substrate 120 and the third substrate 300, and is connected to the second substrate 120 and the third substrate 300. Furthermore, an enclosed area is included in the second frame-shaped resin body 310, so as to enclose a second vacuum space 340 insulated from the outside air among the second frame-shaped resin body 310, the second substrate 120 and the third substrate 300. The first light-transmissive circuit layer 320 is flat placed on the third substrate 300 facing the second vacuum space 340. The first light-transmissive circuit layer 320 may be a metal wire pattern or an ITO transparent electrode. The first LED module 330 is arranged on the third substrate 300 or the first light-transmissive circuit layer 320. The first LED module 330 includes plural first LED chips 331 which are electrically connected to the first light-transmissive circuit layer 320. The second filling material layer 360 with light transmittance is fully filled in the second vacuum space 340, and covers and wraps the first LED module 330, so that no air is contained in the second vacuum space 340, and thus the first LED module 330 is insulated from the air. In this way, no reflection angle exists between the light ray from the first LED module 330 and the first phosphor powder layer 151, and thus the light efficiency reduction of the emitted light can be avoided.

In the variation shown in FIG. 5A, the first light-transmissive circuit layer 320 with light transmittance may be flat placed on the surface of the third substrate 300 facing the second vacuum space 340, so that the first LED module 330 may emit light towards the directions D1 and D2 respectively, thereby making this light source package structure 105A be achieved as emitting light towards two opposite directions.

FIG. 5B illustrates a schematic side view of another variation of FIG. 4C. In addition to having the third substrate 300, the second frame-shaped resin body 310, the first light-transmissive circuit layer 320, the first LED module 330 of FIG. 5A, the light source module 200 also includes a first reflective layer 350 and a first insulating layer 370.

The first reflective layer 350 is positioned on one side surface of the third substrate 300 facing the first substrate 110. The first insulating layer 370 is stacked between the first reflective layer 350 and the first light-transmissive circuit layer 320. The material of the first insulating layer 370 may be SiO₂, TiO₂, Si₃N₄ and so on.

In the variation shown in FIG. 5B, the first insulating layer 370 may be for example a light-transmissive glass. The first LED module 330 is arranged on the first insulating layer 370 or the first light-transmissive circuit layer 320, and electrically connected to the first light-transmissive circuit layer 320. The second filling material layer 360 with light transmittance is fully filled in the second vacuum space 340, and covers and wraps the first LED module 330 and the first light-transmissive circuit layer 320. In this way, when the first LED module 330 emits light towards the directions D1 and D2 respectively, the light emitted towards the direction D2 is reflected by the first reflective layer 350 and then travels towards the direction D1, thereby making this light source package structure 106A be achieved as emitting light towards a single direction.

In particular, the first reflective layer 350 includes a base material 351 and a reflective film 352. The base material 351 is directly stacked on one surface of the third substrate 300. The reflective film 352 is directly stacked between the base material 351 and the first insulating layer 370. The base material 351 may be for example a SiO₂ film, a Cr film and so on. The reflective film 352 may be for example a highly reflective material (such as silver and aluminum) or a multilayer optical reflective film.

FIG. 5C illustrates a schematic side view of a further variation of FIG. 4C. The first LED module 330 includes LED chips 331 with different colors of emitted lights. Those LED chips 331, for example are a red LED chip 331R, a green LED chip 331G and a blue LED chip 331B. Therefore, based on the arrangements required actually, the color rendering and the color temperature size of the required light can be improved after the LED chips 331R, 331G and 331B with different colors of emitted lights are activated by the phosphor powder of the first phosphor powder layer 151.

In the variation shown in FIG. 5C, the first LED module 330 emits light towards the directions D1 and D2 respectively. The light emitted towards the direction D2 is reflected by the first reflective layer 350 and then travels towards the direction D1, thereby making this light source package structure 107A be achieved as emitting light towards a single direction.

In various variations of the aforesaid first embodiment, the area of the third substrate 300 is larger than that of the second substrate 120. Therefore, when flat placed on the surface of the third substrate 300, the first light-transmissive circuit layer 320 may extend out of the second vacuum space 340. That is, the first light-transmissive circuit layer 320 is positioned in the second vacuum space 340 as well as outside the second vacuum space 340, so as to connect with external components for providing the exchange of signals and power sources.

In addition, in various variations of the aforesaid first embodiment, the first LED module 330 may includes one or more LED chips 331 which are disposed with a spot shape (single one), a line shape (1×N), a planar shape (N×N) or other different shapes (such as an annular shape or a polygonal shape).

Furthermore, the second frame-shaped resin body 310 may be a heat-curing resin or a light-curing resin (such as a UV light-curing resin) which can prevent the external air or moisture from permeating. The second filling material layer 340 may be a polymer-stabilized transparent fluid (such as silicon oil) or liquid crystal molecule liquid or transparent gel (such as silica gel).

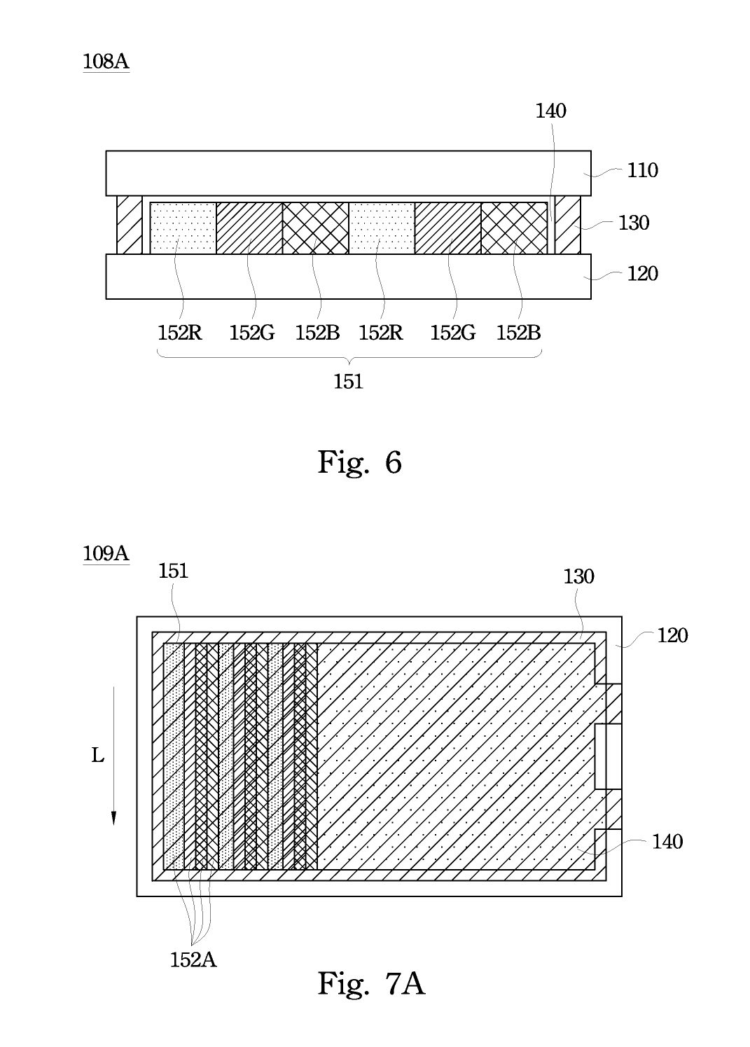

Referring to FIG. 6, it illustrates a schematic side view of an option of the light source package structure 108A in the first embodiment of the present invention.

In the first embodiment, the type of the phosphor powder in the first phosphor powder layer 151 is not limited. The first phosphor powder layer 151 may also include phosphor powder blocks with various light emitting wavebands. It should be emphasized that these phosphor powder blocks with different light emitting wavebands are arranged at intervals on the surface of the first substrate 110 or the second substrate 120. That is, these phosphor powder blocks with different light emitting wavebands are separated distinctly from each other and are not mixed with each other. For example, these phosphor powder blocks includes red phosphor powder blocks 152R, green phosphor powder blocks 152G and blue phosphor powder blocks 152B and so on (as shown in FIG. 6).

For the conventional phosphor powders with different light emitting wavebands which are mixed together, the phosphor powders with the different light emitting wavebands counteract or compensate the existing specific color temperature thereof, and it is difficult to generate a specific color temperature for a specific phosphor powder. However, in the first embodiment of the present invention, since the phosphor powder blocks 152R, 152G and 152B with different light emitting wavebands are separated distinctly from each other and are not mixed, a light with a specific color temperature may be provided for the specific phosphor powder. For example, the red phosphor powder blocks 152R, green phosphor powder blocks 152G and blue phosphor powder blocks 152B may generate a white light with higher coefficient.

Besides, according to the requirements and arrangements of the designers, these phosphor powder blocks may be arranged on the surface of the first substrate 110 or the second substrate 120 for example with spot shapes, or arranged at intervals on the surface of the first substrate 110 or the second substrate 120 with spot shapes along a linear direction. Alternatively, these phosphor powder blocks may be arranged on the surface of the first substrate 110 or the second substrate 120 with bulk shapes in an array manner. However, the present invention is not limited by this. The scale sizes, densities or shapes of the various phosphor powder blocks are not limited.

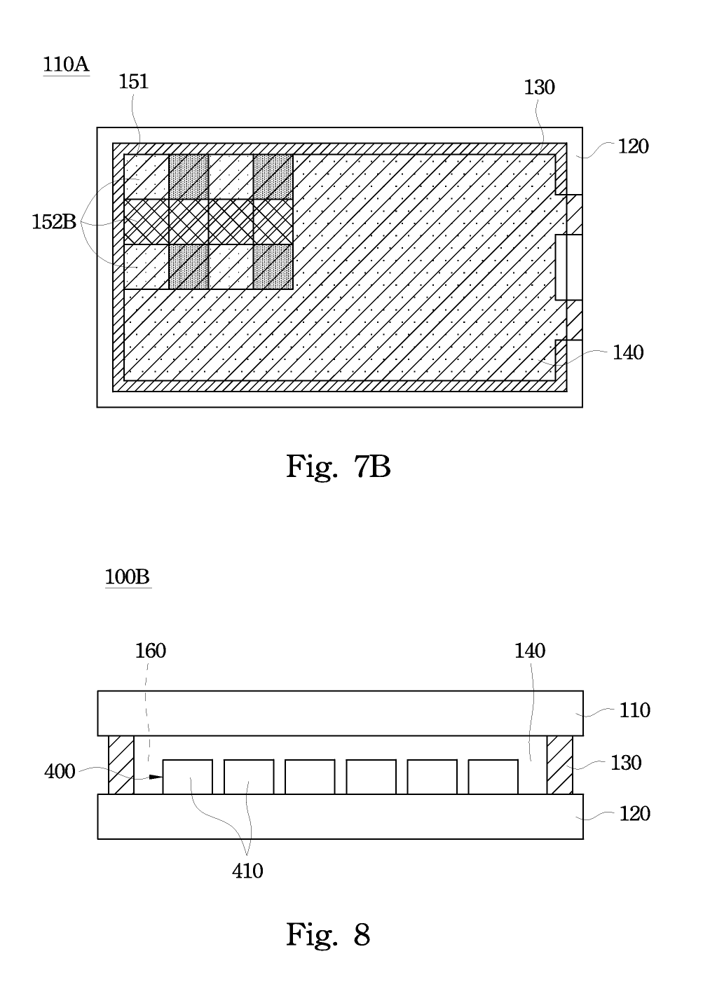

Furthermore, FIG. 7A illustrates a schematic top view of another option of the light source package structure 109A in the first embodiment of the present invention. When these phosphor powder blocks 152A are arranged at intervals on the surface of the first substrate or the second substrate 120 with spot shapes along a linear direction L, these phosphor powder blocks 152A may be sequentially arranged on the surface of the first substrate (not shown) or the second substrate 120 based on the types of the light emitting wavebands, and the phosphor powder blocks 152A with the same waveband are not adjacent to each other. However, the present invention is not limited to this.

FIG. 7B illustrates a schematic top view of a further option of the light source package structure 110A in the first embodiment of the present invention. When these phosphor powder blocks 152B are arranged at intervals on the surface of the first substrate 110 or the second substrate 120 with bulk shapes in an array manner, these phosphor powder blocks 152B may be sequentially arranged on the surface of the first substrate (not shown) or the second substrate 120 based on the types of the light emitting wavebands, and these phosphor powder blocks 152B with the same waveband are not adjacent to each other in the horizontal axis direction and the longitudinal axis direction. However, the present invention is not limited to this.

In the first embodiment, the light source package structure 106A-107A of the present invention may also employ the patents (TW I313518, “Light Emitting Device Capable of Improving Brightness” and TWI298551, “Light Emitting Component Capable of Improving Brightness”) previously applied by the inventor to improve the reflective brightness.

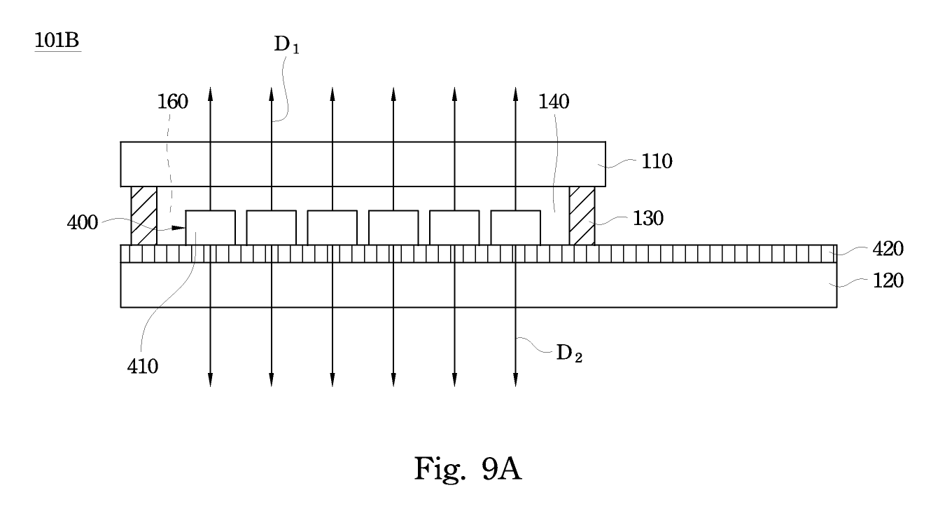

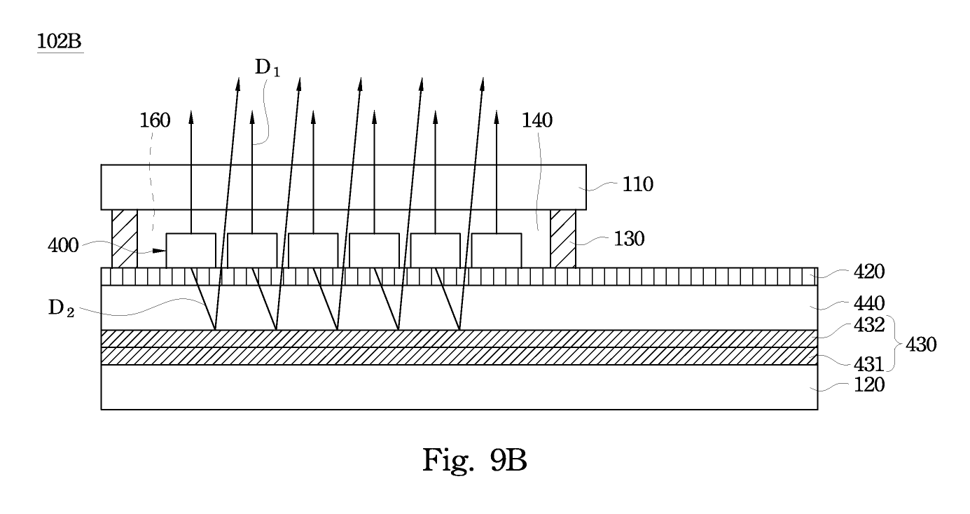

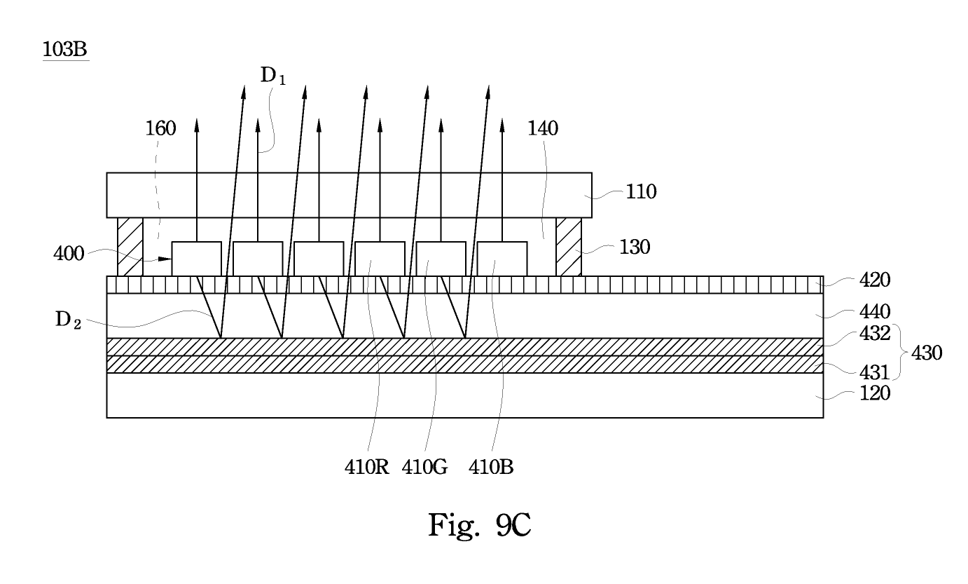

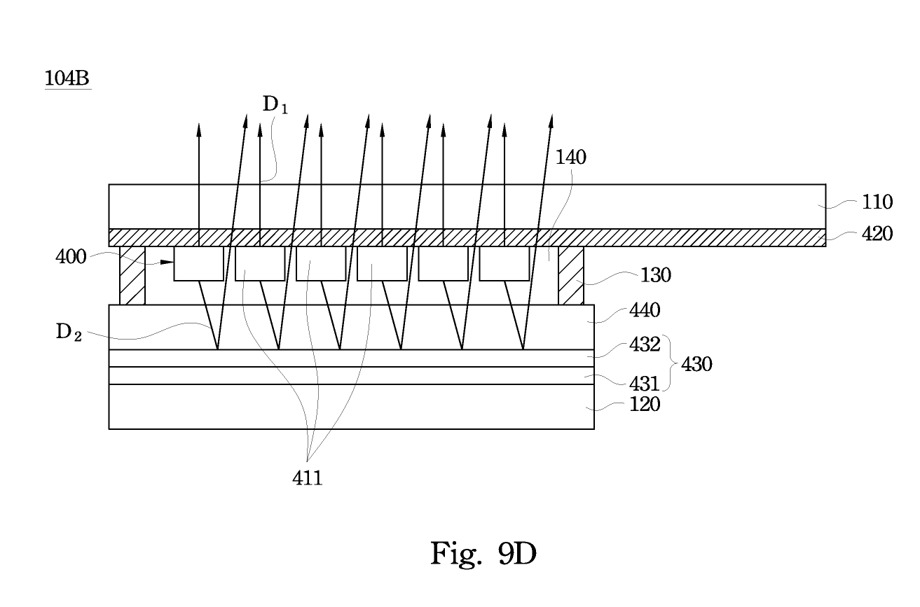

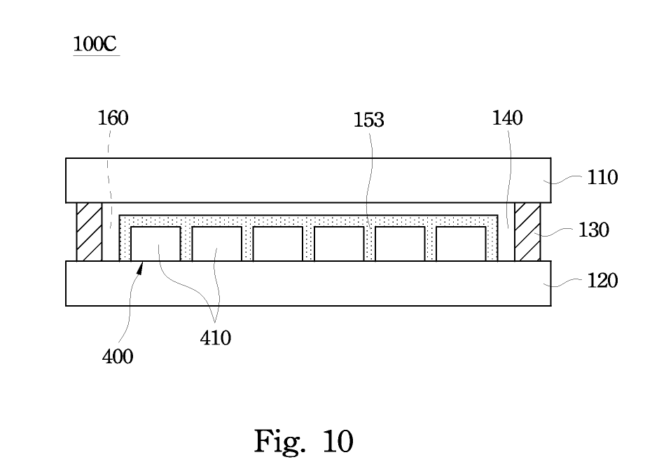

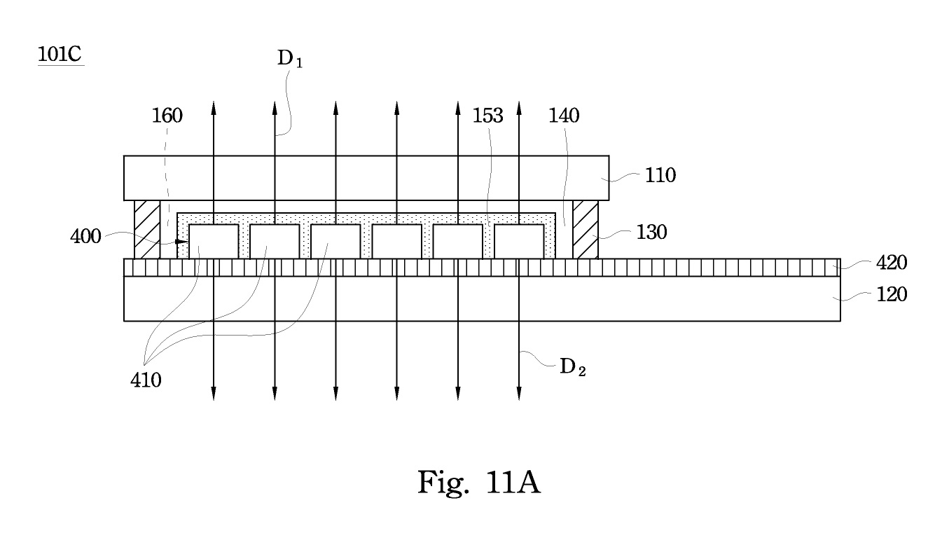

References are made to FIGS. 8 and 9A. FIG. 8 illustrates a schematic side view of the light source package structure 100B in a second embodiment of the present invention. FIG. 9A illustrates a schematic side view of a light source package structure 101B, which is a variation of FIG. 8. In the second embodiment of the aspect, the photoluminescence material 150 includes a second LED module 400. The second LED module 400 is positioned in the first vacuum space 160, and may be arranged on the first substrate 110 or the second substrate 120 (as shown in FIG. 8). The second LED module 400 has one or more second LED chips 410 emitting light directly towards the first substrate 110 or the second substrate 120.

The light source package structure 100B further includes a second light-transmissive circuit layer 420. In the variation shown in FIG. 9A, the second light-transmissive circuit layer 420 is flat placed on the second substrate 120, and the second LED chip 410 is arranged on the second light-transmissive circuit layer 420 and electrically connected to the second light-transmissive circuit layer 420. The second light-transmissive circuit layer 420 may be a metal wire pattern or an ITO transparent electrode. The first substrate 110 is a light-transmissive substrate, such as a light-transmissive glass. The second substrate 120 may be a light-transmissive glass as well as a metal plate, a ceramic plate, a silicon substrate or a quartz plate to achieve the effects of heat dissipation, electric conduction and load bearing. In this way, compared to the package of the prior art, the light source package structure of the present invention can completely insulate the LED chip from the external environment.

In the variation shown in FIG. 9A, the second light-transmissive circuit layer 420 with light transmittance may be flat placed on the surface of the second substrate 120 facing the first vacuum space 160, so that the second LED module 400 can emit light towards the directions D1 and D2 respectively, thereby making this light source package structure 101B be achieved as emitting light towards two opposite directions.

Referring to FIG. 9B, it illustrates a schematic side view of a light source package structure 102B, which is another variation of FIG. 8. The light source package structure 102B further includes a second reflective layer 430 and a second insulating layer 440. The second reflective layer 430 is positioned on one side surface of the second substrate 120 facing the first substrate 110. The second insulating layer 440 is stacked between the second reflective layer 430 and the second light-transmissive circuit layer 420. The material of the second insulating layer 440 may be SiO₂, TiO₂, Si₃N₄ and so on.

In the variation shown in FIG. 9B, the first insulating layer 370 may be for example a light-transmissive glass. The second LED module 400 is arranged on the second insulating layer 440 or the second light-transmissive circuit layer 420, and electrically connected to the second light-transmissive circuit layer 420. In this way, when the second LED module 400 emits light towards the directions D1 and D2 respectively, the light emitted towards the direction D2 is reflected by the second reflective layer 430 and then travels towards the direction D1, thereby making this light source package structure 102B be achieved as emitting light towards a single direction.

In particular, the second reflective layer 430 includes a base material 431 and a reflective film 432. The base material 431 is directly stacked at one surface of the second substrate 120. The reflective film 432 is directly stacked between the base material 431 and the second insulating layer 440. The base material 431 may be for example a SiO₂ film, a Or film and so on. The reflective film 432 may be for example highly reflective material (such as silver and aluminum) or multilayer optical reflective film.

Referring to FIG. 9C, it illustrates a schematic side view of a light source package structure 103B, which is a further variation of FIG. 8. The second LED module 400 includes LED chips with different colors of emitted lights. Those LED chips 410 are for example a red LED chip 410R, a green LED chip 410G and a blue LED chip 410B. Therefore, this light source package structure 103B can be applied to an electronic display unit (such as an electronic advertising board), wherein the graphic or text may be displayed on the first substrate 110 through the LED chips 410R, 410G and 410B with different colors of emitted lights in the second LED module 400.

In various variations of the aforesaid second embodiment, the area of the second substrate 120 is larger than that of the first substrate 110. Therefore, when flat placed on the surface of the second substrate 120, the second light-transmissive circuit layer 420 extends out of the first vacuum space 160. That is, the second light-transmissive circuit layer 420 is positioned in the first vacuum space 160 as well as outside the first vacuum space 160, so as to connect with the external components for providing the exchange of signals and power sources.

Referring to FIG. 9D, it illustrates a schematic side view of a light source package structure 104B, which is yet a further variation of FIG. 8. In a variation of FIG. 9D, the second light-transmissive circuit layer 420 is flat placed on the surface of the first substrate 110 facing the first vacuum space 160. The second LED chips 411 are arranged on the second light-transmissive circuit layer 420 and electrically connected to the second light-transmissive circuit layer 420. The second light-transmissive circuit layer 420 may be a metal wire pattern or an ITO transparent electrode. The first substrate 110 is a light-transmissive substrate, such as a light-transmissive glass. Besides, the second substrate 120 may be also a light-transmissive glass.

In a variation of FIG. 9D, the second reflective layer 430 is positioned on one side surface of the second substrate 120 facing the first substrate 110. The second insulating layer 440 is stacked between the second reflective layer 430 and the second light-transmissive circuit layer 420. The first insulating layer 370 may be for example a light-transmissive glass. In this way, when the second LED chips 411 of the second LED module 400 emit light towards the directions D1 and D2 respectively, the light emitted towards the direction D2 is reflected by the second reflective layer 430 and then travels towards the direction D1, thereby making the light source package structure 104B be achieved as emitting light towards a single direction.

In addition, in this variation, the area of the first substrate 110 is larger than that of the second substrate 120. Therefore, when flat placed on the surface of the first substrate 110, the second light-transmissive circuit layer 420 extends out of the first vacuum space 160. That is, the second light-transmissive circuit layer 420 is positioned in the first vacuum space 160 as well as outside the first vacuum space 160, so as to connect with the external components for providing the exchange of signals and power sources.

However, the present invention is not limited to this. In this variation of the second embodiment, the second insulating layer 440 in FIG. 9D may also be omitted so that the first frame-shaped resin body 130 may be directly sandwiched between the second light-transmissive circuit layer 420 and the second reflective layer 430. This cannot only reduce the material cost, but also shorten the distance between the second LED module 400 and the second reflective layer 430, so as to improve the performance of light reflection.

In addition, in various variations of the aforesaid second embodiment, the second LED module 400 may includes one or more LED chips which are disposed with a spot shape (single one), a line shape (1×N), a planar shape (N×N) or other different shapes (such as a annular shape or a polygonal shape).

In this second embodiment, the light source package structure 102B-104B of the present invention may also employ the patents (TW I313518, “Light Emitting Device Capable of Improving Brightness” and TWI298551, “Light Emitting Component Capable of Improving Brightness”) previously applied by the inventor to improve the reflective brightness.

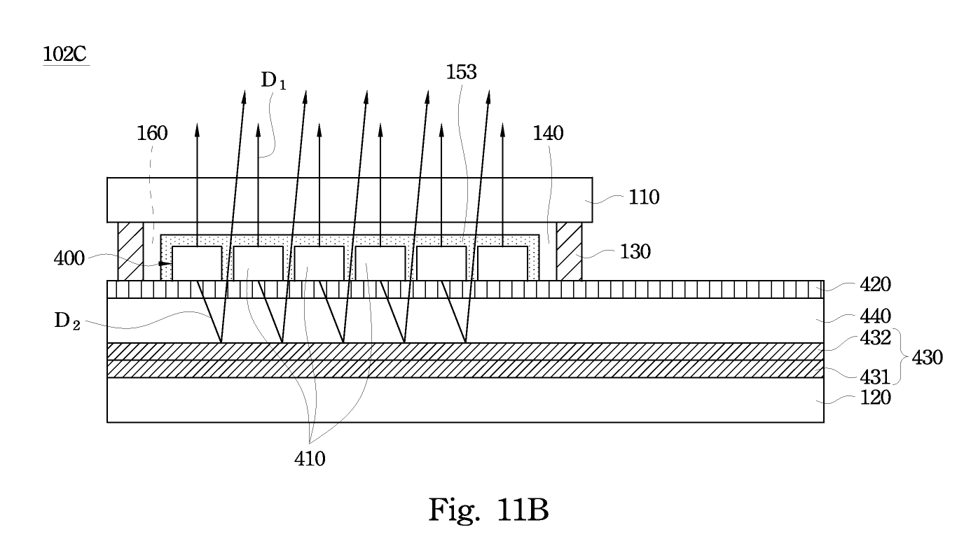

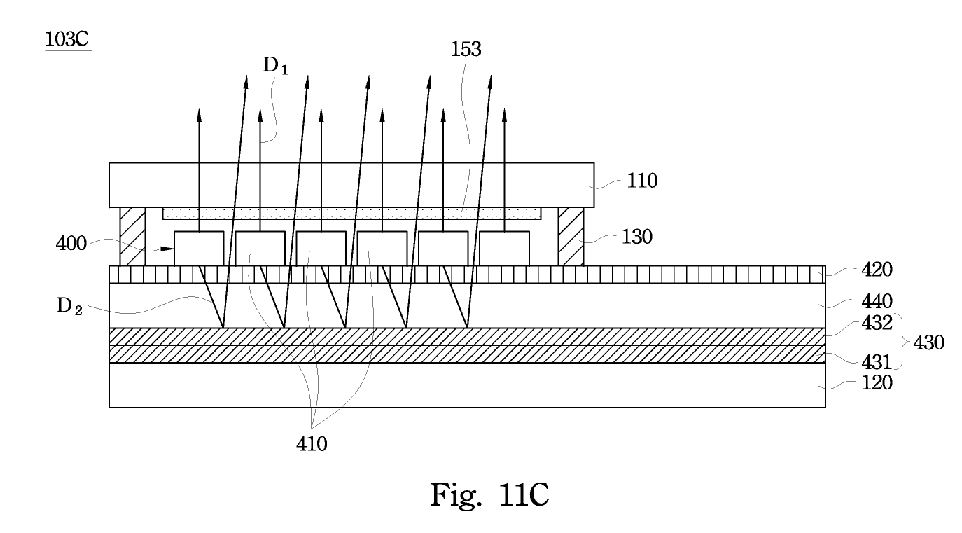

References are made FIGS. 10 and 11A. FIG. 10 illustrates a schematic side view of a light source package structure 100C in a third embodiment of the present invention. FIG. 11A illustrates a schematic side view of a light source package structure 101C, which is a variation of the third embodiment.

In a third embodiment, the photoluminescence object 150 includes both of a second LED module 400 and a second phosphor powder layer 153. The second LED module 400 is not limited to being arranged on the first substrate 110 or the second substrate 120. The second phosphor powder layer 153 is not limited to being coated on the first substrate (not shown) or the second substrate 120 (as shown in FIG. 10).

In the variation shown in FIG. 11A, each of the second LED chips 410 in the second LED module 400 is arranged on the second substrate 120. The second phosphor powder layer 153 is coated on each of the second LED chips 410 in the second LED module 400 and on the second substrate 120, so that the second phosphor powder layer 153 is positioned on the top of each of the LED chips in the second LED module 400 as well as on the second substrate 120. That is, the second LED module 400 is positioned between the second phosphor powder layer 153 and the second light-transmissive circuit layer 420. In the prior art, a gap still exist between the LED chip and the phosphor, which causes generation of an angle of total reflection and thus reduces the light efficiency, while in the third embodiment, the gap between the LED chip and the phosphor is eliminated, thereby improving the light efficiency greatly. Furthermore, the rest structures of the light source package structure 101C in FIG. 11A may be understood with reference to the description of FIG. 9A, and thus it is not illustrated herein any more.

Referring to FIG. 11B, it illustrates a schematic side view of a light source package structure 102C, which is another variation of the third embodiment of the present invention.

In the third embodiment, the light source package structure 102C of the present invention may be also combined with a reflective layer and an insulating layer. Thus, when the second LED module 400 emits light towards the directions D1 and D2 respectively, the light emitted towards the direction D2 is reflected by the first reflective layer 430 and then travels towards the direction D1, thereby making the light source package structure 102C be achieved as emitting light towards a single direction. Furthermore, the rest structures of the light source package structure 102C in FIG. 11B may be understood with reference to the description of FIG. 9B, and thus it is not illustrated herein any more.

Referring to FIG. 11C, it illustrates a schematic side view of a light source package structure 103C, which is a further variation of the third embodiment of the present invention. In the variation shown in FIG. 11C, the second LED module 400 is arranged on the second substrate 120. The second phosphor powder layer 153 is coated on the surface of the first substrate 110, so that the second phosphor powder layer 153 is close to the top of each of the LED chips in the second LED module 400. That is, the second LED module 400 is positioned between the second phosphor powder layer 153 and the second light-transmissive circuit layer 420.

Referring to FIG. 9C again, in the third embodiment, the light source package structure 103C of the present invention may also be combined with the design of FIG. 9C. The second LED module 400 includes LED chips with different colors of emitted lights. Those LED chips are for example a red LED chip 410R, a green LED chip 410G and a blue LED chip 410B. Therefore, the light source package structure 103C may be applied to an electronic display unit (such as an electronic advertising board). The graphic or text may be displayed on the first substrate 110 through the LED chips 410R, 410G and 410B with different colors of emitted lights in the second LED module 400.

In addition, referring to FIG. 9D again, in the third embodiment, the light source package structure 1046 of the present invention may also be combined with the design of FIG. 9D, so that the second LED module 400, the second phosphor powder layer 153 and the first filling material layer 140 are all positioned in the first vacuum space 160.

In various variations of the aforesaid third embodiment, the area of the second substrate 120 is larger than that of the first substrate 110. Therefore, when flat placed on the surface of the second substrate 120, the second light-transmissive circuit layer 420 extends out of the first vacuum space 160. That is, the second light-transmissive circuit layer 420 is positioned in the first vacuum space 160 as well as outside the first vacuum space 160, so as to connect with the external components for providing the exchange of signals and power sources.

In addition, in various variations of the aforesaid third embodiment, the second LED module 400 may includes one or more LED chips which are disposed with a spot shape (single one), a line shape (1×N), a planar shape (N×N) or other different shapes (such as a annular shape or a polygonal shape).

In the third embodiment, the light source package structure 102C-103C of the present invention may also employ the patents (TW I313518, “Light Emitting Device Capable of Improving Brightness” and TWI298551, “Light Emitting Component Capable of Improving Brightness”) previously applied by the inventor to improve the reflective brightness.

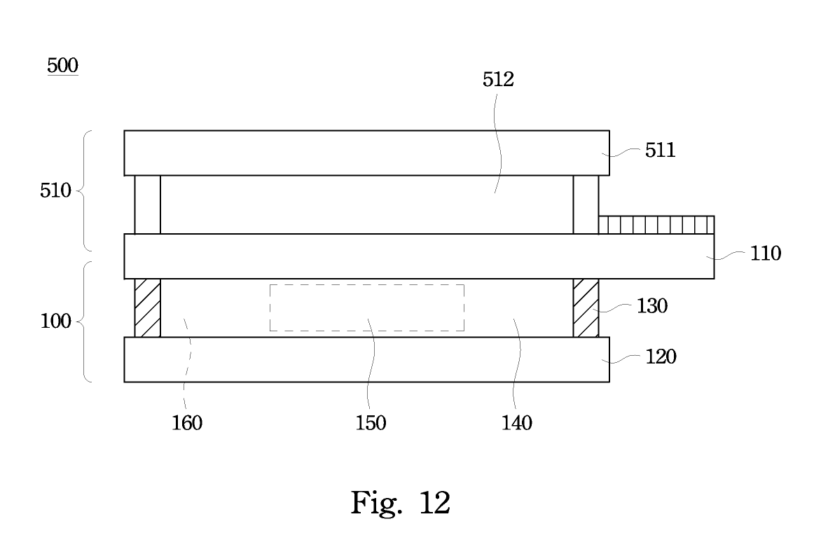

Referring to FIG. 12, it illustrates a schematic side view of a liquid crystal display (LCD) 500 combined with the light source package structure 100 in a fourth embodiment of the present invention. The LCD 500 includes a liquid crystal panel 510 and an aforesaid light source package structure 100. In general, the liquid crystal panel includes an upper substrate, a lower substrate and a liquid crystal layer. The liquid crystal layer is packaged between the upper substrate and the lower substrate.

In the fourth embodiment, the liquid crystal panel 510 includes an upper substrate 511 and a liquid crystal layer 512. The first substrate 110 of the aforesaid light source package structure 100 is the lower substrate of the liquid crystal panel 510. That is, the liquid crystal layer 512 is directly sandwiched between the upper substrate 511 of the liquid crystal panel 510 and the first substrate 110 of the light source package structure 100. Thus, the LCD 500 of the present invention can not only reduce the material cost of a sheet of glass substrate, but also shorten the distance of the light traveling to the liquid crystal panel 510.

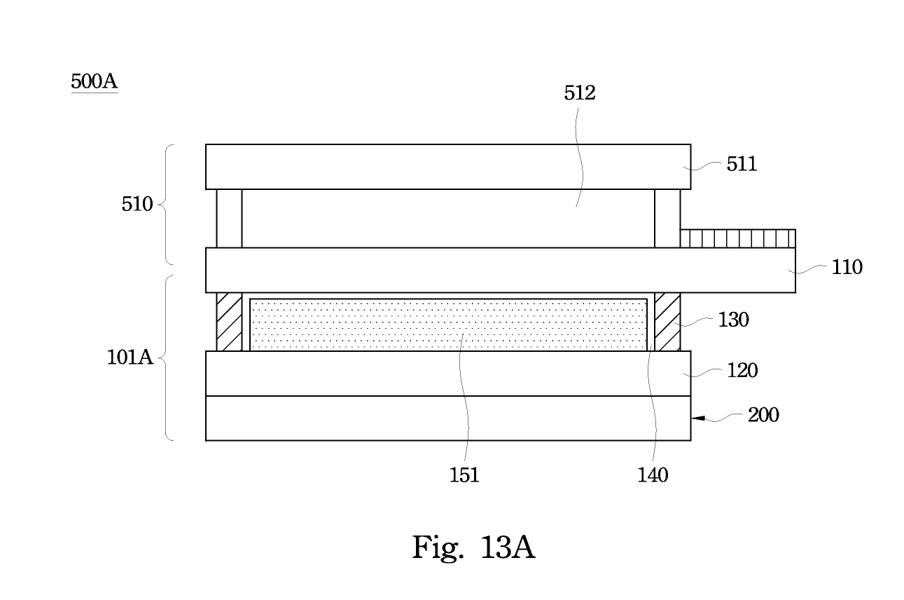

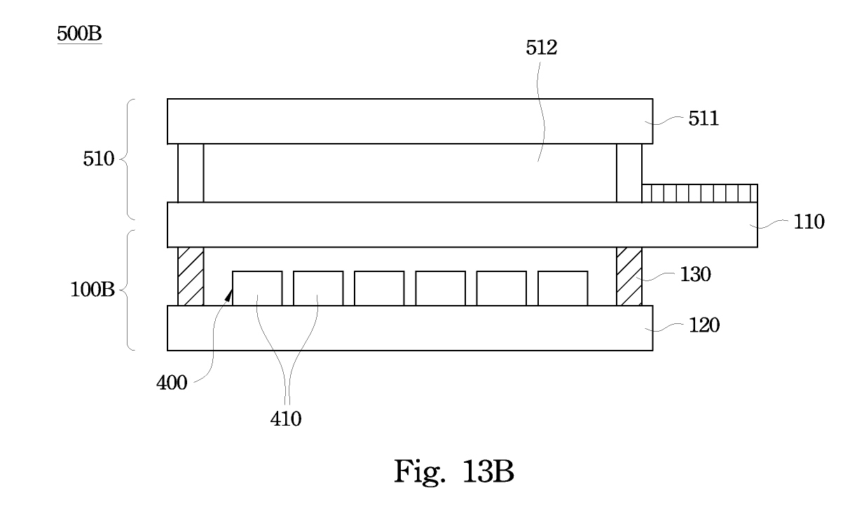

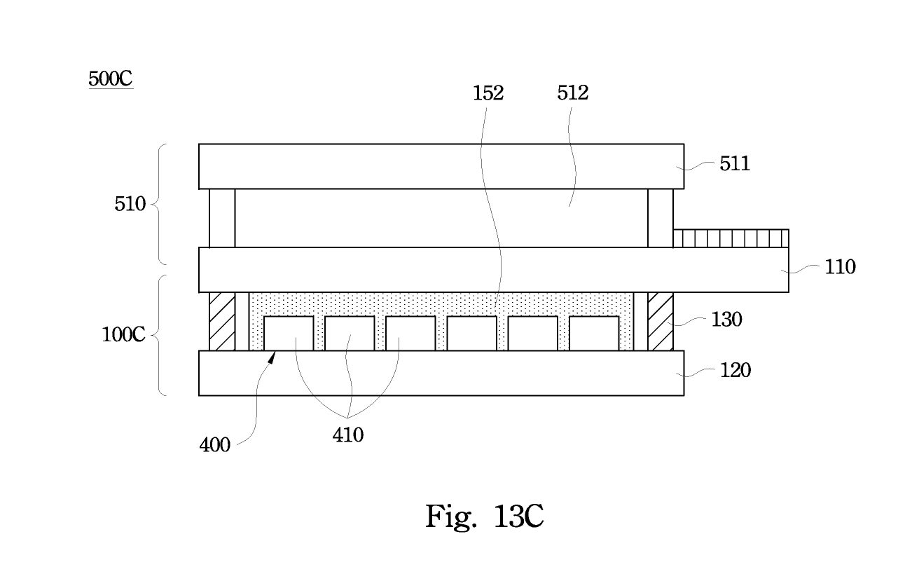

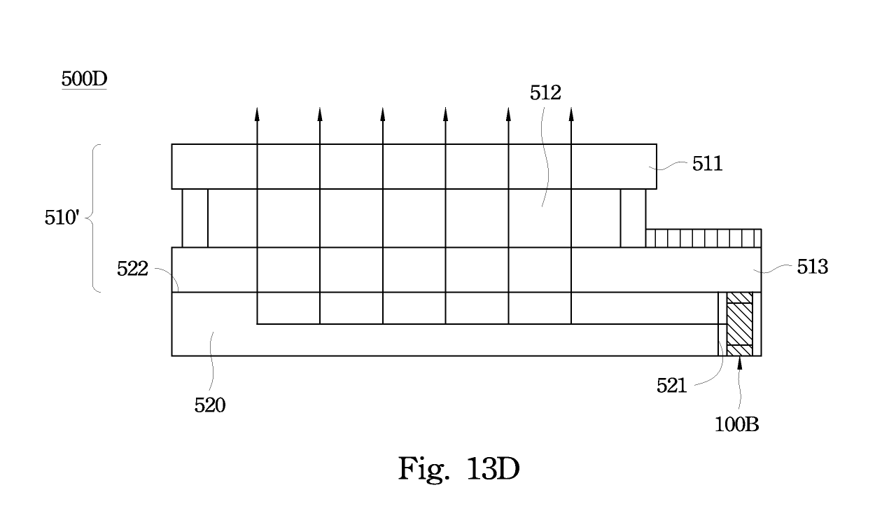

Referring to FIG. 13A, it illustrates a schematic side view of the LCD 500 combined with the light source package structure 100A, which is a variation of the fourth embodiment of the present invention.

This variation is that the liquid crystal panel 510 is combined with the design of the aforesaid light source package structure 101A which is combined with the light source module 200 in the first embodiment of the present invention, wherein the light source module 200 may be understood with reference to the variations shown in FIGS. 3-5C. Therefore, the light emitted by the light source module 200 can be converted into a white light or a visible light through the first phosphor powder layer 151, so as to provide sufficient light source for the liquid crystal panel 510.

Referring to FIG. 13B, it illustrates a schematic side view of the LCD 500 combined with the light source package structure 100B, which is another variation of the fourth embodiment of the present invention.

This variation is that the liquid crystal panel 510 is combined with the design of the aforesaid light source package structure 100B of the second embodiment of the present invention, wherein the variation of the second LED module 400 may be understood with reference to the variation shown in FIGS. 9A-9D. Therefore, sufficient light source can be provided to the liquid crystal panel 510 through the light emitted by the second LED module 400.

Referring to FIG. 13C, it illustrates a schematic side view of the LCD 500 combined with the light source package structure 100C, which is a further variation of the fourth embodiment of the present invention.

This variation is that the liquid crystal panel 510 is combined with the design of the aforesaid light source package structure 100C in the third embodiment of the present invention, wherein the variation of the second LED module 400 and the second phosphor powder layer 153 may be understood with reference to the variation shown in FIGS. 11A-11C. Therefore, sufficient light source can be provided to the liquid crystal panel 510 through the light emitted by the second LED module 400 and the second phosphor powder layer 153.

Referring to FIG. 13D, it illustrates a schematic side view of the LCD 500 combined with the light source package structure 1008, which is yet a further variation of the fourth embodiment of the present invention. In this variation, the liquid crystal panel 510 is combined with a side view type LED module formed by the aforesaid light source package structure 100B of the present invention.

The liquid crystal panel 510′ includes an upper substrate 511, a lower substrate 513 and a liquid crystal layer 512. The liquid crystal layer 512 is packaged between the upper substrate 511 and the lower substrate 513. The light source package structure 100B is combined with a light guide plate 520 which is positioned at one side of the liquid crystal panel 510 and has a light entrance surface 521 and a light exist surface 522. The light source package structure 100B is positioned on the light entrance surface 521 of the light guide plate 520 in the side view type, and emits light towards the light entrance surface 521. The light exist surface 522 of the light guide plate 520 faces the liquid crystal panel 510.

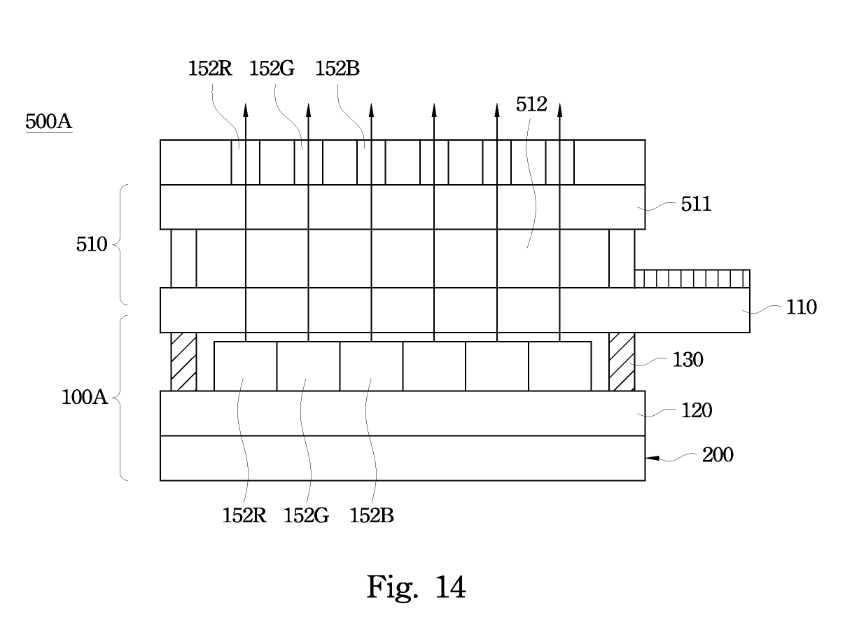

Referring to FIG. 14, it illustrates a schematic side view of the LCD 500 combined with the light source package structure 100A, which is a further variation of the fourth embodiment of the present invention.

The liquid crystal panel 510 further includes a colored filter 530 which is positioned outside the upper substrate 511 and has plural uniformly distributed pixel gratings. Those pixel gratings include at least a red pixel grating 531R, a green pixel grating 531G and a blue pixel grating 531B. This variation is that the liquid crystal panel 510 is combined with the design of the aforesaid light source package structure 100A which is combined with the phosphor powder blocks with plural light emitting wavebands in the first embodiment of the present invention. The first phosphor powder layer 151 includes a phosphor powder block 152R with a red light waveband, a phosphor powder block 152G with a green light waveband and a phosphor powder block 152B with a blue light waveband, which are separated from each other. As such, the red phosphor block 152R faces directly the red pixel grating 531R, the green phosphor block 152G faces directly the green pixel grating 531G, and the blue phosphor block 152B faces directly the blue pixel grating 531B.

Since a phosphor powder block faces directly a pixel grating with the same color, when the light is excited by the phosphor powder block with a specific color, the colored light provided by the phosphor powder block will not be blocked by the pixel grating with the same color, thereby increasing the color rendering index of the whole liquid crystal panel, and strengthening the required color temperature based on the requirement. However, the present invention is not limited to this, and the first phosphor powder layer may also use a phosphor powder layer with a single waveband herein.

The first substrate 110, the second substrate 120 or the third substrate 300 mentioned above in the present invention may be 0.2-2 mm thick. The gap between any two of the first substrate 110, the second substrate 120 and the third substrate 300 may be 5 μm-250 μm. However, with the evolution of techniques, the thickness of the first substrate 110, the second substrate 120 or the third substrate 300 and the gap mentioned above in the present invention are not limited to these.

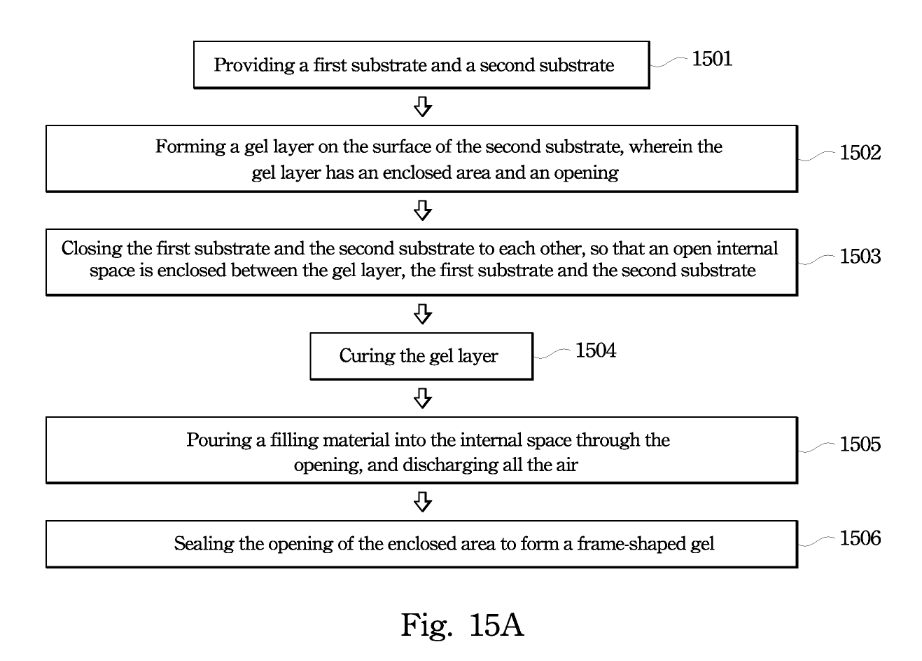

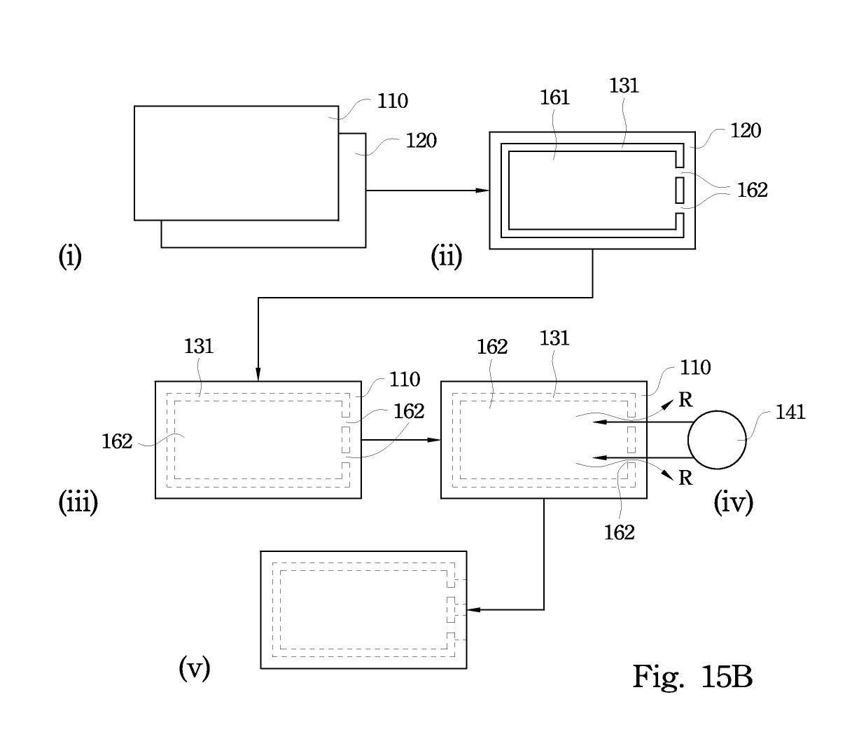

Referring to FIG. 15A, it illustrates a flow chart of the fabricating method of the light source package structure of the present invention. FIG. 15B illustrates a schematic operation flow chart of the fabricating method of the light source package structure of the present invention. The present invention further provides another fabricating method of the aforesaid light source package structure, and the method includes the preliminary steps as follows.

Step (1501): a first substrate 110 and a second substrate 120 (as shown in FIG. 15B(i)) are provided respectively.

Step (1502): a resin layer 131 is formed (such as coated) on the surface of the second substrate 120, wherein the resin layer 131 has an enclosed area 161 with at least one opening 162 (as shown in FIG. 15B(ii)).

In this step, the material of the resin layer 131 is for example a heat-curing resin or a light-curing resin. Thus, in an option achieving this step, the resin layer 131 is coated on the surface of the second substrate 120 by the way of printing.

Step (1503): the first substrate 110 and the second substrate 120 are covered to each other (as the first substrate 110 and the second substrate 120 are closed to each other), so that the resin layer 131 is positioned between the first substrate 110 and the second substrate 120, and an open internal space 163 (as shown in FIG. 15B(iii)) is enclosed by the resin layer 131, the first substrate 110 and the second substrate 120 together.

Step (1504): the resin layer 131 is cured.

In this step, since the material of the resin layer 131 is for example a heat-curing resin or a light-curing resin, the curing method may be heating the resin layer 131 or emitting UV light to the resin layer 131, so as to make the resin layer 131 be cured. Here, when the resin is cured, the resin is solidified.

Step (1505): a filling material 141 is filled into the internal space 163 through the opening 162, and all the air R in the internal space 163 is discharged to form the aforesaid first vacuum space (as shown in FIG. 15B(iv)).

In an option achieving this step, since the filling material is a liquid crystal molecule liquid, silicon ill or liquid silica gel under a high temperature, the filling material may be filled into the internal space through the opening.

In another option achieving this step, since the filling material is a liquid crystal molecule liquid, silicon ill or liquid silica gel under a high temperature, the internal space may be maintained under a vacuum negative pressure state firstly, and then the filling material is introduced into the internal space through the pressure of the vacuum negative pressure.

Step (1506): the opening 162 is sealed to form the aforesaid frame-shaped resin body which seals the filling material in the first vacuum space.

In an option achieving this step, a resin material is dispensed to the opening 162 in the enclosed area 161, so as to generate an airtight element 132 in the opening 162 for sealing the filling material 141 in the first vacuum space 160 (as shown in FIG. 15B(iv)).

Therefore, after at least steps (1501)-(1506) are performed, the aforesaid light source package structure of the present invention is formed.

Furthermore, the present invention may select other cutting processes to form plural aforesaid light source package structures.

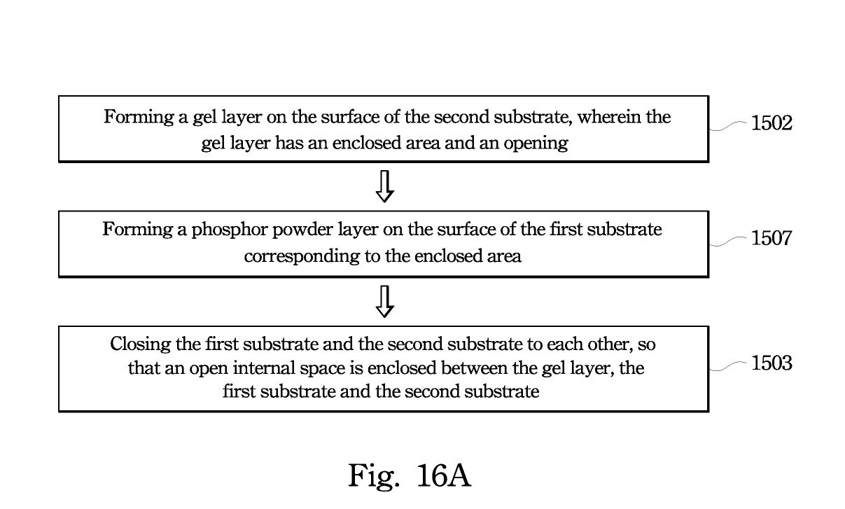

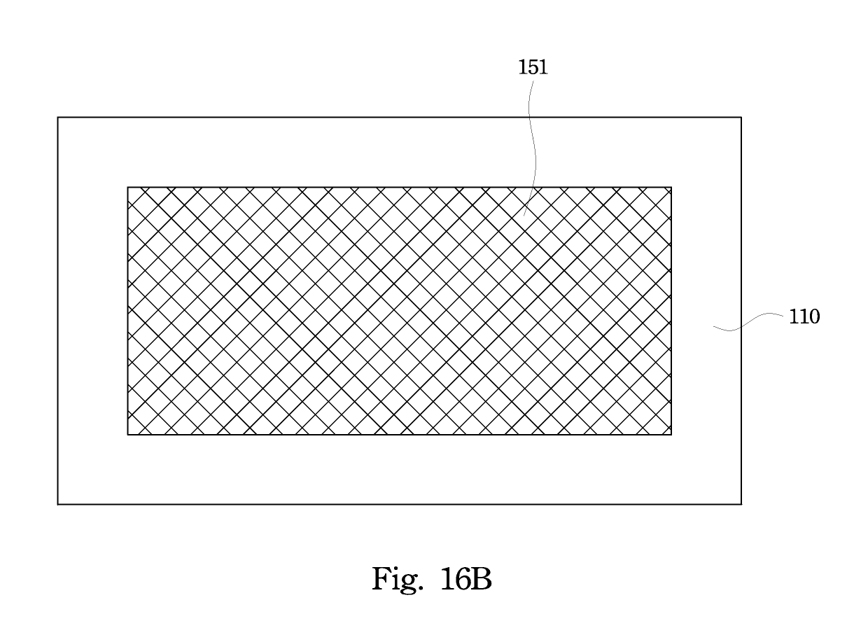

Referring to FIG. 16A, it illustrates a partially detailed flow chart of the fabricating method of the light source package structure 100A in the first embodiment of the present invention. Referring to FIG. 16B, it illustrates a schematic operation flow chart of the fabricating method of the light source package structure 100A in the first embodiment of the present invention.

When the light source package structure 100A is the first embodiment of the present invention, the following detailed steps are further included between the step (1501) and the step (1503):

In the step (1507), phosphor particles are sprayed to form (such as coat) one or more phosphor powder layers 151 on the surface of the first substrate 110 corresponding to the aforesaid enclosed area 161. Therefore, when the first substrate 110 covers on the second substrate 120, the phosphor powder layer 151 is packaged in the first vacuum space 160. Since the phosphor particles may be attached onto the surface of the first substrate 110, the phosphor powder layers 151 with different wavebands can be arranged at intervals on the surface of the first substrate 110, so as to avoid mixture of the phosphor powders.

Furthermore, in another option of this detailed step, the phosphor powder layer may also be formed on the surface of the second substrate and positioned within the aforesaid enclosed area. The phosphor powder layer can be packaged in the first vacuum space as long as the first substrate covers on the second substrate.

It should be understood that the steps (1507) and (1502) may be performed independently and the performing sequence thereof is not limited. It is only required to ensure that the phosphor powder layer is positioned in the aforesaid enclosed area when the first substrate covers on the second substrate in the step (1503).

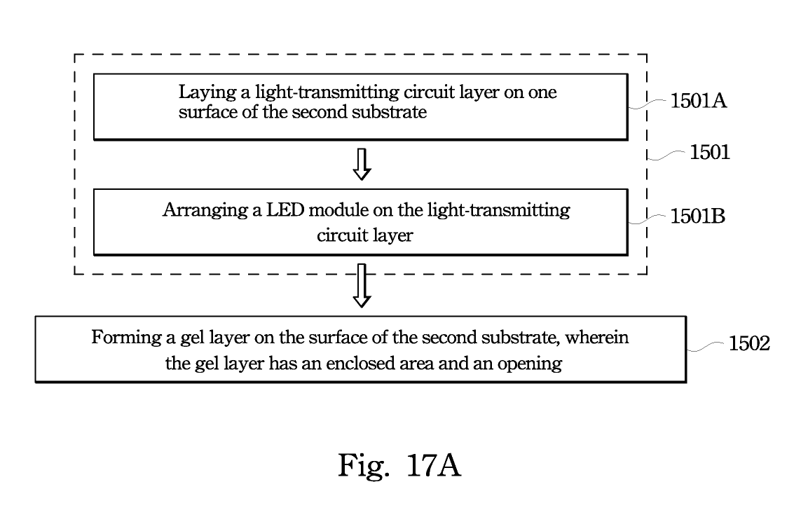

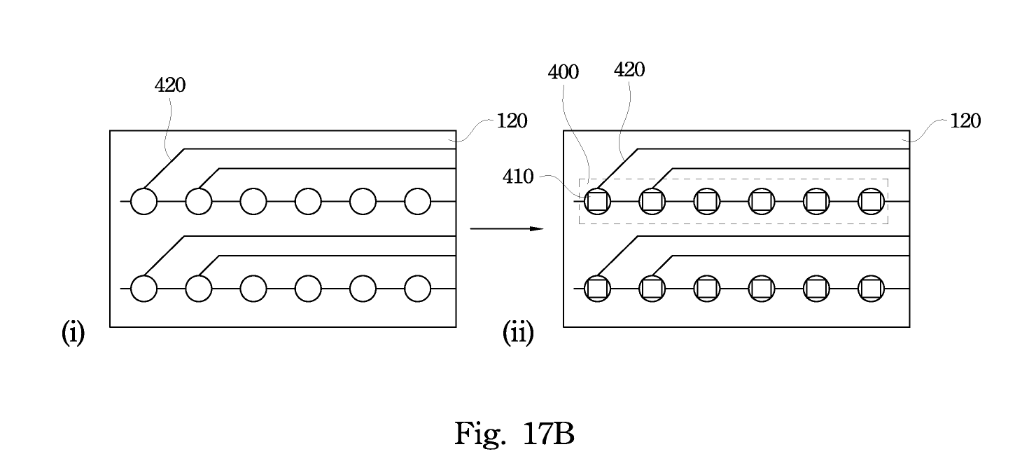

Referring to FIG. 17A, it illustrates a partially detailed flow chart of the fabricating method of the light source package structure 100B in the second embodiment of the present invention. FIG. 17B illustrates a schematic operation flow chart of the fabricating method of the light source package structure in the second embodiment of the present invention.

When the light source package structure 100B is the second embodiment of the present invention, the following detailed steps are further included in the step (1501):

Step (1501A): an aforesaid light-transmissive circuit layer 420 is flat placed on one surface of the second substrate 120 (as shown in FIG. 17B(i)).

Step (1501B): at least one LED module 400 is arranged on the light-transmissive circuit layer 420, wherein the LED module 400 is positioned in the enclosed area, and the LED module 400 is electrically connected to the light-transmissive circuit layer 420 (as shown in FIG. 17B(ii)).

Therefore, when the first substrate covers on the second substrate, the LED module is packaged in the first vacuum space.

Furthermore, in another option of this detailed step, the light-transmissive circuit layer may also be flat placed on the surface of a first glass substrate and positioned in the aforesaid enclosed area. The LED module can be packaged in the first vacuum space as long as the first substrate covers on the second substrate.

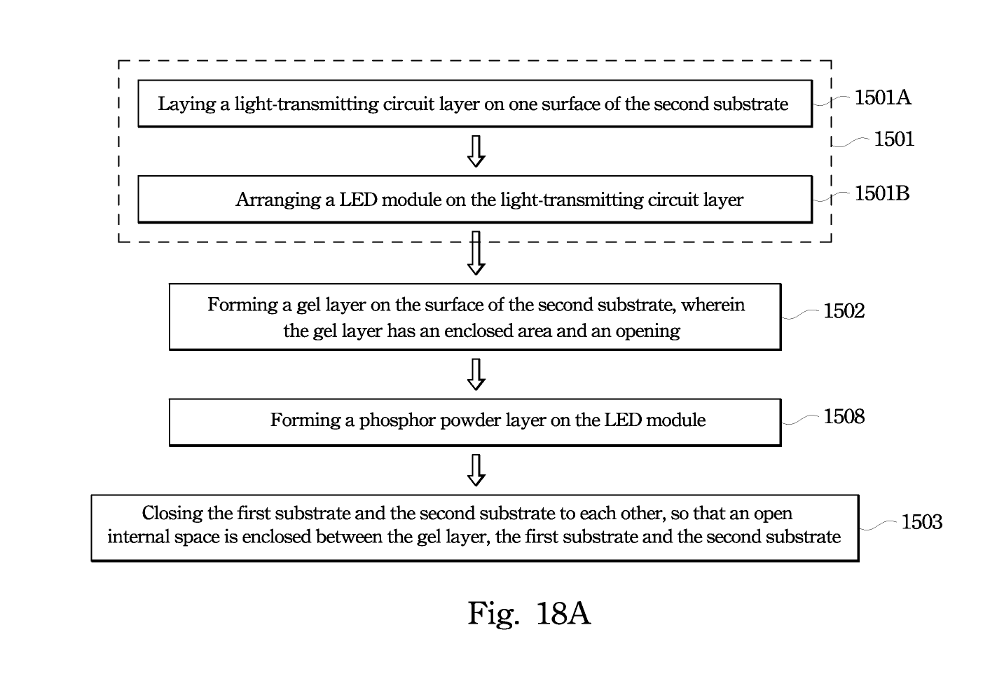

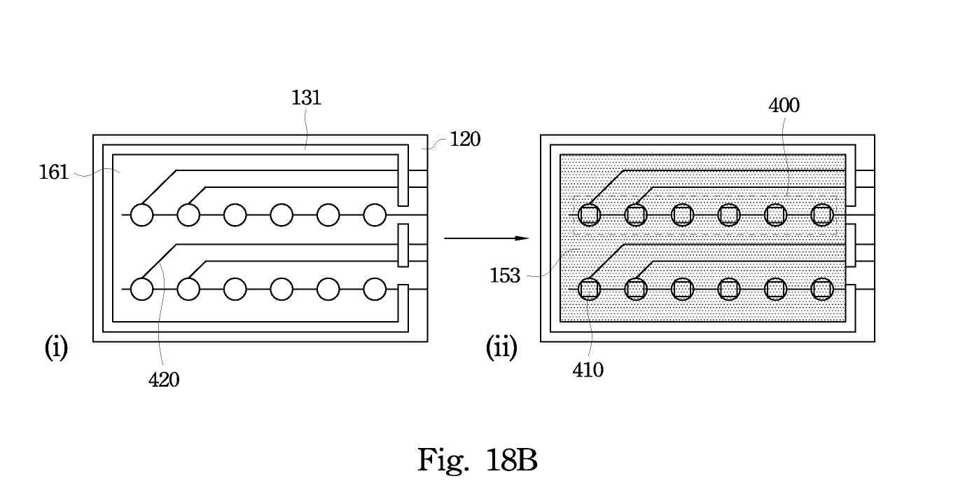

Referring to FIG. 18A, it illustrates a partially detailed flow chart of the fabricating method of the light source package structure 100C in the third embodiment of the present invention. FIG. 18B illustrates a schematic operation flow chart of the fabricating method of the light source package structure in the third embodiment of the present invention.

When the light source package structure 100C is the third embodiment of the present invention, the following detailed steps are further included in the step (1501):

Step (1501A): an aforesaid light-transmissive circuit layer 420 is flat placed on one surface of the second substrate 120 (as shown in FIG. 17B(i)).

Step (1501B): at least one LED module 400 is arranged on the light-transmissive circuit layer 420, wherein the LED module 400 is positioned in the enclosed area, and the LED module 400 is electrically connected to the light-transmissive circuit layer 420 (as shown in FIG. 17B(ii)).

In addition, the following detailed steps are further included between the step (1502) and the step (1503):

Step (1508): the phosphor particles are sprayed to form one or more phosphor powder layers 153 coated on the LED module 400 (as shown in FIG. 18B(ii)). Therefore, when the first substrate 110 covers on the second substrate 120, the LED module 400 and the phosphor powder layer 153 are packaged in the first vacuum space 160.

It should be understood that, in the conventional coating process of the white phosphor powder (resin), some phosphor powder with high efficiency and strong reactivity may be unable to exert its light efficiency due to the changes of environment. On the contrary, the fabricating method provided by the present invention can be operated in the environment of inert gases. In this way, the phosphor in the process is difficult to react with the oxygen or other active molecules resulting in reduce of the light efficiency thereof. In this process, some phosphors with extremely high activity and efficiency may also be used in a normal-temperature or low-temperature environment so as to maintain the original reliability and light efficiency of the phosphor.

Although the present invention has been disclosed with reference to the above embodiments, these embodiments are not intended to limit the present invention. It will be apparent to those of skills in the art that various modifications and variations can be made without departing from the spirit and scope of the present invention. Therefore, the scope of the present invention shall be defined by the appended claims.

1. A light source package structure, comprising:
a first substrate which is a light-transmissive glass;
a second substrate overlapped with the first substrate;
a first frame-shaped resin body disposed between the first substrate and the second substrate, and coupled to the first substrate and the second substrate, enclosing a first vacuum space together with the first substrate and the second substrate;
a photoluminescence object as a passive luminophor, positioned in the first vacuum space; and
a filling material layer with light transmittance, fully filled in the first vacuum space, and wrapping the photoluminescence object; and
a light source module positioned at one side of the second substrate opposite to the first vacuum space, emitting light towards the photoluminescence object and the first substrate.

2. The light source package structure of claim 1, wherein the second substrate is a light-transmissive glass.

3. The light source package structure of claim 2, wherein the photoluminescence object comprises a first phosphor powder layer, and the first phosphor powder layer is coated on one surface of the second substrate or the first substrate.

4. The light source package structure of claim 2, wherein the photoluminescence object comprises a first phosphor powder layer, and the first phosphor powder layer is mixed in the first filling material layer.

5. The light source package structure of claim 2, wherein the photoluminescence object comprises a first phosphor powder layer, the first phosphor powder layer is formed by phosphor powder blocks with various light emitting wavebands, and the phosphor powder blocks with the different light emitting wavebands are arranged at intervals.

6. (canceled)

7. The light source package structure of claim 1, wherein the light source module is a top view type light emitting diode (LED) module or a side view type LED module.

8. The light source package structure of claim 1, wherein the light source module comprises:
a third substrate;
a second frame-shaped resin body disposed between the second substrate and the third substrate, and coupled to the second substrate and the third substrate, enclosing a second vacuum space together with the second substrate and the third substrate;
a first light-transmissive circuit layer flat placed on the third substrate and positioned in the second vacuum space;
a first LED module arranged on the first light-transmissive circuit layer and electrically connected to the first light-transmissive circuit layer; and
a second filling material layer fully filled in the second vacuum space, and wrapping the first LED module.

9. The light source package structure of claim 8, wherein the light source module further comprises:
a first reflective layer disposed on one side surface of the third substrate facing the first substrate; and
a first insulating layer stacked between the first reflective layer and the first light-transmissive circuit layer.

10. The light source package structure of claim 8, wherein the first LED module comprises LED chips with different light emitting colors.

11. The light source package structure of claim 28, wherein the second substrate is a light-transmissive glass, a metal plate, a ceramic plate or a silicon substrate.

12. The light source package structure of claim 11 further comprising:
a second light-transmissive circuit layer flat placed on the second substrate or the first substrate, wherein the second LED module is arranged on the second light-transmissive circuit layer and electrically connected to the second light-transmissive circuit layer.

13. The light source package structure of claim 12, further comprising:
a second reflective layer positioned on one side surface of the second substrate facing the first substrate; and
a second insulating layer stacked between the second reflective layer and the second light-transmissive circuit layer.

14. The light source package structure of claim 13, wherein the second reflective layer comprises:
a base material directly stacked on one surface of the second substrate; and
a reflective film directly stacked between the base material and the second insulating layer.

15. (canceled)

16. The light source package structure of claim 11, wherein the second LED module is positioned between the second phosphor powder layer and the second light-transmissive circuit layer.

17. The light source package structure of claim 28, wherein the second LED module comprises LED chips with different light emitting colors.

18. The light source package structure of claim 28, wherein the first frame-shaped resin body is a heat-curing resin or a light-curing resin respectively.

19. The light source package structure of claim 28, wherein the first filling material layer is a liquid crystal molecule liquid, silicon oil or silica gel.

20. A liquid crystal display, comprising:
a light source package structure of claim 1; and
a liquid crystal panel comprising an upper substrate and a liquid crystal layer, wherein the liquid crystal layer is directly sandwiched between the first substrate and the upper substrate.

21. The liquid crystal display of claim 20, wherein the liquid crystal panel further comprises:
a colored filter positioned at one side of the upper substrate far away from the liquid crystal layer, comprising a red pixel grating, a green pixel grating and a blue pixel grating; and
the first phosphor powder layer comprises a phosphor powder block with a red light waveband, a phosphor powder block with a green light waveband and a phosphor powder block with a blue light waveband, which are separated from each other,
wherein the phosphor powder block with the red light waveband faces directly the red pixel grating, the phosphor powder block with the green light waveband faces directly the green pixel grating and the phosphor powder block with the blue light waveband faces directly the blue pixel grating.

22. A fabricating method of a light source package structure, comprising:
providing a first substrate and a second substrate;
forming a resin layer on a surface of the second substrate, wherein the resin layer has an enclosed area with an opening;
directly coating a phosphor powder layer on one surface of the first substrate or the second substrate;
covering the first substrate on the second substrate, so as to enclose an internal space between the resin layer, the first substrate and the second substrate, and the phosphor powder layer is in the internal space;
curing the resin layer;
filling a filling material into the internal space through the opening;
sealing the opening to seal the filling material in the internal space; and
providing a light source module on one side of the second substrate opposite to the internal space.

23-25. (canceled)

26. The fabricating method of the light source package structure of claim 22, wherein the step of filling a filling material into the internal space through the opening further comprises:
maintaining the internal space under a vacuum negative pressure state, and introducing the filling material into the internal space through the vacuum negative pressure state.

27. The fabricating method of the light source package structure of claim 22, wherein the filling material is a liquid crystal molecule liquid, silicon oil or liquid silica gel.

28. A light source package structure, comprising:
a first substrate which is a light-transmissive glass;
a second substrate overlapped with the first substrate;
a first frame-shaped resin body disposed between the first substrate and the second substrate, and coupled to the first substrate and the second substrate, enclosing a first vacuum space together with the first substrate and the second substrate;
a second phosphor powder layer positioned in the first vacuum space, and coated on one surface of the first substrate or the second substrate;
a second LED module positioned in the first vacuum space; and
a first filling material layer with light transmittance, fully filled in the first vacuum space, and wrapping the second LED module and second phosphor powder layer.

29. The light source package structure of claim 8, wherein the first frame-shaped resin body and the second frame-shaped resin body are a heat-curing resin or a light-curing resin respectively.

30. The light source package structure of claim 8, wherein the first filling material layer and the second filling material layer are a liquid crystal molecule liquid, silicon oil or silica gel.
